(19) United States
(12) Patent Application Publication
(10) Pub. No.: US 2025/0255175 A1
(43) Pub. Date: Aug. 7, 2025

(54) INK COMPOSITION, LIGHT EMITTING ELEMENT MANUFACTURED THROUGH THE SAME, AND MANUFACTURING METHOD OF THE LIGHT EMITTING ELEMENT

(71) Applicant: Samsung Display Co., Ltd., Yongin-si (KR)

(72) Inventors: Jungho JO, Yongin-si (KR); DONGWOO SHIN, Yongin-si (KR); YUNKU JUNG, Yongin-si (KR); YUNHYUK KO, Yongin-si (KR)

(73) Assignee: Samsung Display Co., Ltd., Yongin-si (KR)

(21) Appl. No.: 18/975,024

(22) Filed: Dec. 10, 2024

(30) Foreign Application Priority Data
Feb. 6, 2024 (KR) 10-2024-0018287

(51) Int. Cl. H10K 85/30; B82Y 20/00; B82Y 40/00; C09D 11/037; C09D 11/52; H10K 50/115; H10K 50/155; H10K 71/12; H10K 85/40

(52) U.S. Cl. CPC H10K 85/361; C09D 11/037; C09D 11/52; H10K 85/40; B82Y 20/00; B82Y 40/00; H10K 50/115; H10K 50/155; H10K 71/12

(57) ABSTRACT

Embodiments provide a light emitting element, an ink composition, and a method of manufacturing a light emitting element using the ink composition. The light emitting element includes a first electrode, a second electrode disposed on the first electrode, an emission layer disposed between the first electrode and the second electrode, and a hole transport region disposed between the first electrode and the emission layer, wherein the hole transport region includes nanoparticles, and the nanoparticles each include a core represented by Formula 1, which is explained in the specification.

Ni₁₋ₓMₓO. [Formula 1]

### CROSS-REFERENCE TO RELATED APPLICATION(S)

This application claims priority to and benefits of Korean Patent Application No. 10-2024-0018287 under 35 U.S.C. § 119, filed on Feb. 6, 2024, in the Korean Intellectual Property Office, the entire contents of which are incorporated herein by reference.

### BACKGROUND

### 1. Technical Field

The disclosure relates to an ink composition, a light emitting element manufactured through the same, and a manufacturing method of the light emitting element.

### 2. Description of the Related Art

Various display devices have been developed for use in multimedia devices such as a television set, a mobile phone, a tablet computer, a navigation unit, and a game console. Such display devices use a so-called self-luminescent display element which achieves display by causing a luminescent material including an organic compound to emit light.

Development of a light emitting element using quantum dots as a light emitting material has been conducted in order to enhance the color reproducibility of display devices, and there is a demand for increasing the luminous efficiency and service life of a light emitting element using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminous efficiency and an element service life are improved.

The disclosure also provides an ink composition capable of improving luminescence characteristics and an element service life of the light emitting element.

The disclosure also provides a method for producing a light emitting element having improved process reliability.

According to an embodiment, a light emitting element may include: a first electrode; a second electrode disposed on the first electrode; an emission layer disposed between the first electrode and the second electrode; and a hole transport region disposed between the first electrode and the emission layer, the hole transport region including nanoparticles, wherein the nanoparticles may each include a core represented by Formula 1:

Ni₁₋ₓMₓO [Formula 1]

In Formula 1, M may be Zn, Sn, Ti, Cu, Mg, or Cr; and x may satisfy 0<x<1.

In an embodiment, in Formula 1, x may satisfy 0.01≤x<0.03.

In an embodiment, in Formula 1, M may be Zn.

In an embodiment, the nanoparticles may each further include ligands bonded to a surface of the core.

In an embodiment, the ligand may include at least one of 2-(2-methoxyethoxy)ethanamine, 2-(2-methoxyethoxy) acetic acid, and 2-(2-methoxyethoxy)ethanethiol.

In an embodiment, an amount of the ligands may be in a range of about 10 wt % to about 30 wt % with respect to 100 wt % of a total weight of the nanoparticles.

In an embodiment, the hole transport region may further include an additive represented by Formula 2:

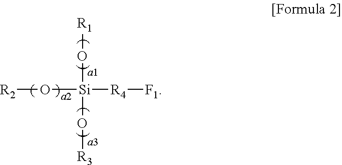

In Formula 2, R₁ to R₃ may each independently be a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 60 ring-forming carbon atoms, or a substituted or unsubstituted heteroaryl group having 2 to 60 ring-forming carbon atoms; R₄ may be a substituted or unsubstituted alkylene group having 1 to 30 carbon atoms, a substituted or unsubstituted cycloalkylene group having 3 to 30 ring-forming carbon atoms, a substituted or unsubstituted arylene group having 6 to 60 ring-forming carbon atoms, or a substituted or unsubstituted heteroarylene group having 2 to 60 ring-forming carbon atoms; a1 to a3 may each independently be 0 or 1, provided that at least one of a1 to a3 may be 1; and F₁ may be a substituted or unsubstituted (meth)acrylate group, a substituted or unsubstituted epoxy group, or a substituted or unsubstituted amine group.

In an embodiment, the additive may be represented by one of Formula 3-1 to Formula 3-5:

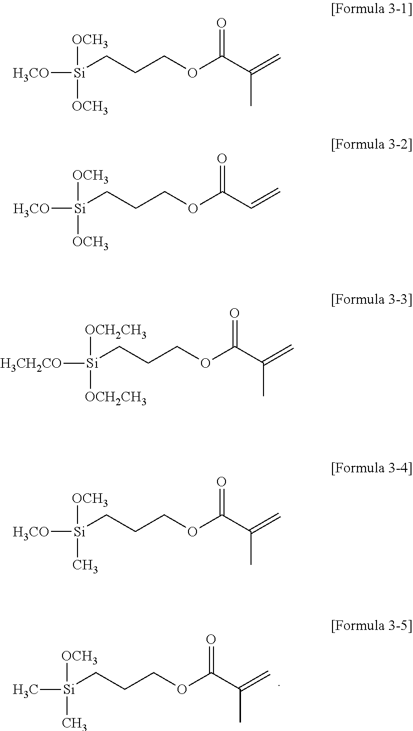

In an embodiment, the emission layer may include quantum dots.

In an embodiment, the light emitting element may further include an electron transport region disposed between the second electrode and the emission layer, wherein the electron transport region may include a metal oxide.

In an embodiment, the metal oxide may include at least one of ZnO, ZnSnO, ZnMgO, SnO₂, and ZnGaO.

According to an embodiment, an ink composition may include nanoparticles, wherein the nanoparticles may each include a core represented by Formula 1:

Ni₁₋ₓMₓO [Formula 1]

In Formula 1, M may be Zn, Sn, Ti, Cu, Mg, or Cr; and x may satisfy 0.01≤x<0.03.

In an embodiment, in Formula 1, M may be Zn.

In an embodiment, the nanoparticles may each further include ligands bonded to a surface of the core.

In an embodiment, the ligand may include at least one of 2-(2-methoxyethoxy)ethanamine, 2-(2-methoxyethoxy) acetic acid, and 2-(2-methoxyethoxy)ethanethiol.

In an embodiment, an amount of the ligands may be in a range of about 10 wt % to about 30 wt % with respect to 100 wt % of a total weight of the nanoparticles.

In an embodiment, the ink composition may further include an additive represented by Formula 2:

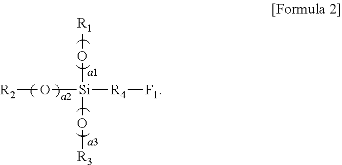

In Formula 2, R₁ to R₃ may each independently be a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 60 ring-forming carbon atoms, or a substituted or unsubstituted heteroaryl group having 2 to 60 ring-forming carbon atoms; R₄ may be a substituted or unsubstituted alkylene group having 1 to 30 carbon atoms, a substituted or unsubstituted cycloalkylene group having 3 to 30 ring-forming carbon atoms, a substituted or unsubstituted arylene group having 6 to 60 ring-forming carbon atoms, or a substituted or unsubstituted heteroarylene group having 2 to 60 ring-forming carbon atoms; a1 to a3 may each independently be 0 or 1, provided that at least one of a1 to a3 may be 1; and F₁ may be a substituted or unsubstituted (meth)acrylate group, a substituted or unsubstituted epoxy group, or a substituted or unsubstituted amine group.

According to an embodiment, a method for manufacturing a light emitting element may include: forming a hole transport region on a first electrode; forming an emission layer on the hole transport region; forming an electron transport region on the emission layer; and forming a second electrode on the electron transport region, wherein the forming of the hole transport region may include preparing an ink composition including nanoparticles, providing the ink composition on the first electrode to form a preliminary hole transport region, and heat-treating the preliminary hole transport region; and the nanoparticles may each include a core represented by Formula 1:

Ni₁₋ₓMₓO [Formula 1]

In Formula 1, M may be Zn, Sn, Ti, Cu, Mg, or Cr; and x may satisfy 0<x<1.

In an embodiment, the forming of the emission layer may include: providing, on the hole transport region, a quantum dot composition including quantum dots to form a preliminary emission layer; and heat-treating the preliminary emission layer.

In an embodiment, the forming of the electron transport region may include: providing, on the emission layer, an electron transport composition including a metal oxide to form a preliminary electron transport region; and heat-treating the preliminary electron transport region.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will be more apparent by describing in detail embodiments thereof with reference to accompanying drawings, in which:

FIG. 1 is a schematic perspective view of a display device according to an embodiment;

FIG. 2 is a schematic cross-sectional view of the display device corresponding to virtual line I-I′ of FIG. 1 according to an embodiment;

FIG. 3 is a schematic plan view of a display device according to an embodiment;

FIG. 4 is a schematic cross-sectional view of a display device according to the embodiment;

FIGS. 5A and 5B are each a schematic cross-sectional view of a light emitting element according to an embodiment;

FIG. 6 is a flowchart of a method for manufacturing a light emitting element according to an embodiment;

FIG. 7 is a flowchart of a divided step of forming a hole transport region according to an embodiment;

FIG. 8 is a schematic cross-sectional view of an ink composition according to an embodiment; and

FIGS. 9A to 9C are each a schematic cross-sectional view of method steps for manufacturing a light emitting element according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a heteroaryl group may include at least one of B, O, N, P, Si, and S as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 50, 2 to 40, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkyl aryl group, an alkyl silyl group, or an alkyl amine group may be the same as an example of an alkyl group as described above.

In the specification, an aryl group within an aryl silyl group, or an arylamine group may be the same as an example of an aryl group as described above.

In the specification, the term “(meth)acrylate” may be interpreted as meaning “acrylate or methacrylate”.

In the specification, the symbol [symbol] represents a bond to a neighboring atom in a corresponding formula or moiety.

Hereinafter, an ink composition according to an embodiment, a light emitting element formed from the same, and a method for manufacturing the light emitting element will be described with reference to the accompanying drawings.

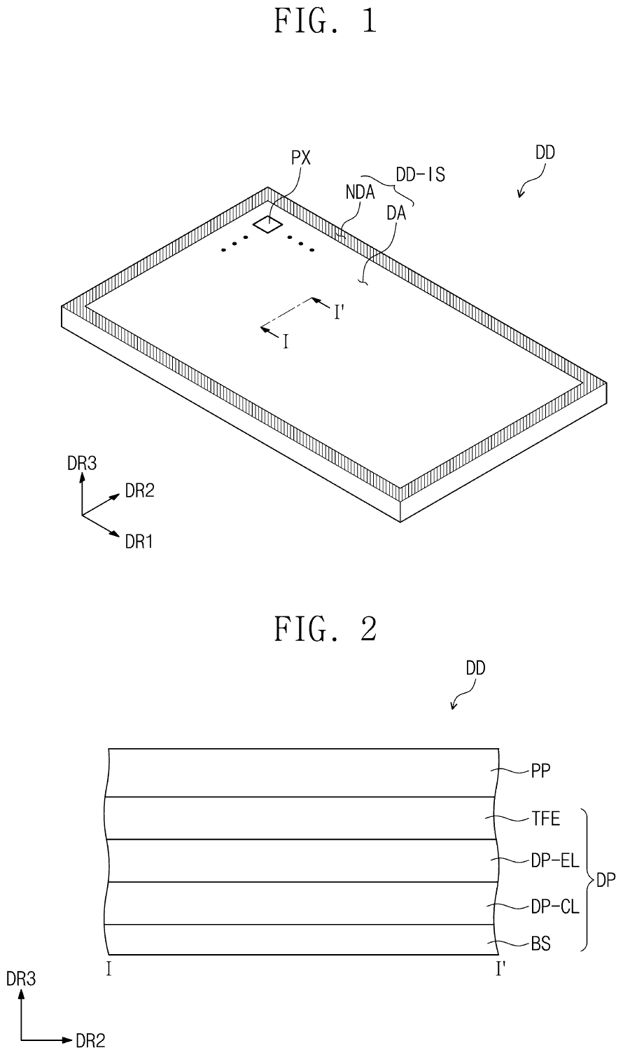

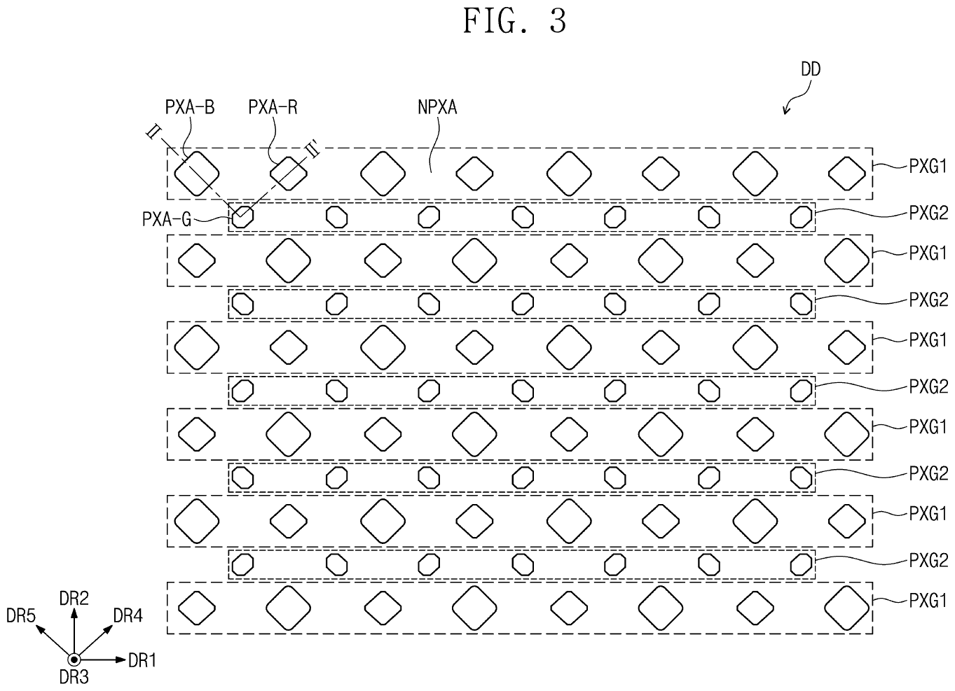

FIG. 1 is a schematic perspective view of a display device according to an embodiment. FIG. 2 is a schematic cross-sectional view of a display device DD according to an embodiment, corresponding to virtual line I-I′ of FIG. 1.

Referring to FIG. 1, the display device DD according to an embodiment may be activated by an electrical signal. For example, the display device DD may be a large device such as a television, a monitor, or an outdoor billboard. The display device DD may be a small or medium-sized device, such as a personal computer, a laptop computer, a personal digital terminal, a car navigation system, a game console, a smart phone, a tablet computer, or a camera. These devices are merely presented as examples, and thus the display device DD may be adopted for other electronic devices within the scope of the embodiments.

The display device DD may display an image (or a video) through a display surface DD-IS. The display surface DD-IS may be parallel to a plane that is defined by a first direction DR1 and a second direction DR2. The display surface DD-IS may include a display region DA and a non-display region NDA.

Pixels PX may be disposed in the display region DA, and the pixels PX may not be disposed in the non-display region NDA. The non-display region NDA may be defined by the edges of the display surface DD-IS. The non-display region NDA may surround (for example, entirely surround) the display region DA. However, embodiments are not limited thereto, and the non-display region NDA may be omitted, or the non-display region NDA may be disposed only on a side of the display region DA.

FIG. 1 illustrates that the flat display surface DD-IS of the display device DD is flat, but embodiments are not limited thereto. The display device DD may have a curved display surface or a three-dimensional display surface. The three-dimensional display surface may include multiple display areas extending in different directions.

FIG. 1, as well as the remaining figures, illustrate a first direction DR1, a second direction DR2, and a third direction DR3, and the directions indicated by the first to third directions DR1, DR2, and DR3 described in this specification are relative concepts and may be converted into other directions. In the specification, the first direction DR1 and the second direction DR2 may be orthogonal to each other, and the third direction DR3 may be a normal line direction with respect to a plane defined by the first direction DR1 and the second direction DR2. In the specification, the term “plane” or “plan view” may refer to a plane that is defined by the first direction DR1 and the second direction DR2, and the term “cross-section” or “cross-sectional view” may refer to a surface that is perpendicular to the plane defined by the first direction DR1 and the second direction DR2, and parallel to the third direction DR3. The display device DD may have a thickness direction parallel to a third direction DR3 that is a normal direction with respect to the plane defined by the first direction DR1 and the second direction DR2.

In this specification, a top surface (or a front surface) and a bottom surface (or a rear surface) of each member constituting the display device DD may be defined with respect to the third direction DR3. For example, among two surfaces facing each other with respect to the third direction DR3 in one member, a surface relatively adjacent to the display surface DD-IS may be defined as a front surface (or a top surface), and a surface spaced relatively apart from the display surface DD-IS may be defined as a rear surface (or a bottom surface). In the specification, the upper portion (or upper side) and the lower portion (or lower side) may be defined with respect to the third direction DR3, and the upper portion (or upper side) may be defined in a direction closer to the display surface DD-IS, and the lower portion (or lower side) may be defined in a direction distal from the display surface DD-IS.

FIG. 2 is a schematic cross-sectional view of a portion taken along virtual line I-I′ of FIG. 1. FIG. 2 may be a schematic cross-sectional view of the display device according to an embodiment.

The display device DD may include a display panel DP and an optical member PP disposed on the display panel DP. The display panel DP may include a base substrate BS, a circuit layer DP-CL disposed on the base substrate BS, a display element layer DP-EL disposed on the circuit layer DP-CL, and an encapsulation layer TFE disposed on the display element layer DP-EL.

The display panel DP may generate a video. The display panel DP may be a light emitting display panel. For example, the display panel DP may be a quantum dot light emitting display panel that includes a quantum dot light emitting element.

The base substrate BS may provide a base surface on which the circuit layer DP-CL is disposed. The base substrate BS may be a rigid substrate, or it may be a flexible substrate that is bendable, foldable, rollable, or the like. The base substrate BS may be a glass substrate, a metal substrate, or a polymer substrate. However, embodiments are not limited thereto, and the base substrate BS may include an inorganic layer, an organic layer, or a composite material layer.

The circuit layer DP-CL may be disposed on the base substrate BS. The circuit layer DP-CL may include an insulation layer, a semiconductor pattern, a conductive pattern, a signal line, etc. The insulating layer, the semiconductor layer, and the conductive layer may be formed on the base substrate BS through methods such as coating or vapor deposition, and the insulating layer, the semiconductor layer, and the conductive layer may be selectively patterned through iterations of a photolithography process. Thus, a semiconductor pattern, a conductive pattern, and a signal line, which are included in the circuit layer DP-CL, may be formed.

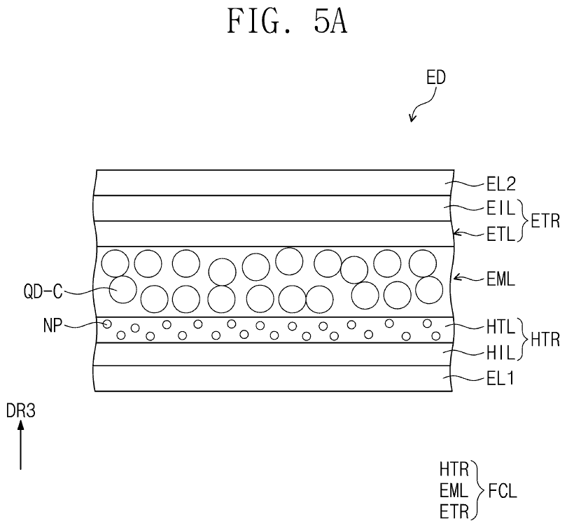

The display element layer DP-EL may be disposed on the circuit layer DP-CL. The display element layer DP-EL may include the pixel defining film PDL (see FIG. 4) and first to third light emitting elements ED-1, ED-2, and ED-3 (see FIG. 4). For example, the display element layer DP-EL may include an organic light emitting material, an inorganic light emitting material, an organic-inorganic light emitting material, quantum dots, quantum rod, a micro LED, or a nano LED. For example, the display element layer DP-EL may include quantum dots.

The encapsulation layer TFE may protect the display element layer DP-EL from foreign substances such as moisture, oxygen, and dust particles. The encapsulation layer TFE may include at least one inorganic layer. The encapsulation layer TFE may include a structure of an inorganic layer, an organic layer, and an inorganic layer, which may be stacked in that order.

The optical member PP may be disposed on the display panel DP and may control light that is reflected at the display panel DP from an external light. The optical member PP may include, for example, a polarizing layer (not shown) or a color filter layer CFL (see FIG. 4). Although not shown in the drawings, in an embodiment, the optical member PP may be omitted.

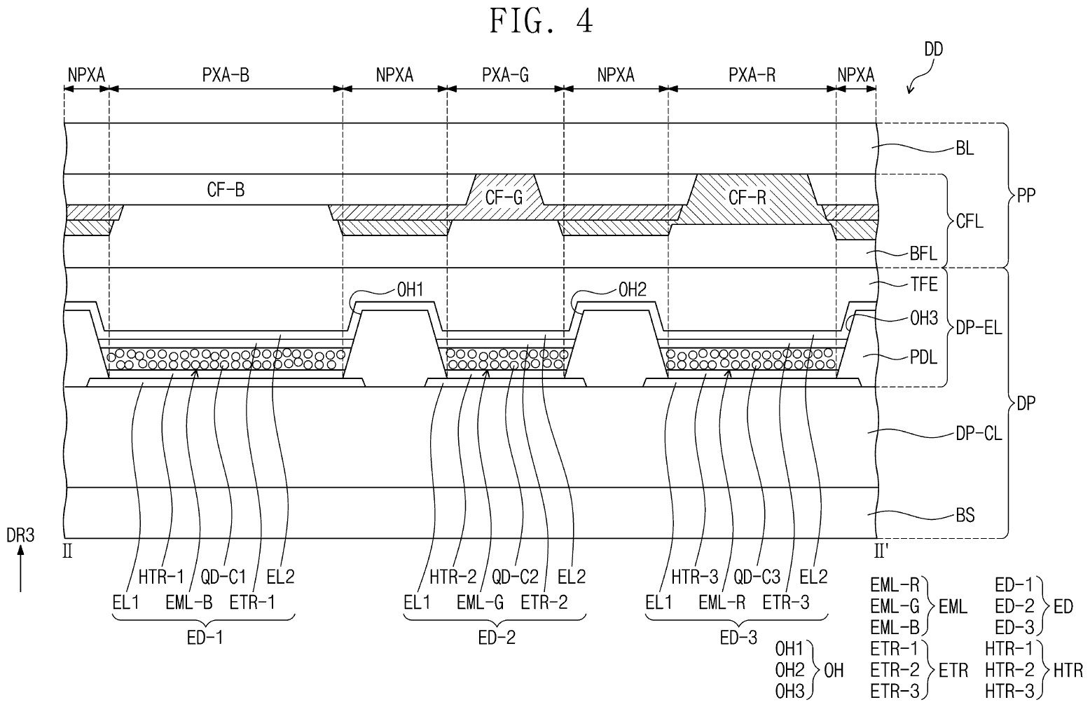

FIG. 3 is a schematic plan view of a display device according to an embodiment. FIG. 4 is a schematic cross-sectional view of a display device according to an embodiment. FIG. 4 is a schematic cross-sectional view of a part taken along virtual line II-II′ of FIG. 3.

Referring to FIGS. 3 and 4, the display device DD according to an embodiment multiples of each of the light emitting elements ED-1, ED-2, and ED-3. In an embodiment, the display device DD may include a display panel DP including the light emitting elements ED-1, ED-2, and ED-3, and an optical member PP disposed on the display panel DP. Although not shown in the drawings, the optical member PP may be omitted from the display device DD according to an embodiment.

The display panel DP may include a base substrate BS, a circuit layer DP-CL, and a display element layer DP-EL provided on the base substrate BS, and the display element layer DP-EL may include a pixel defining film PDL, light emitting elements ED-1, ED-2, and ED-3 disposed between the pixel defining film PDL, and an encapsulation layer TFE disposed on the light emitting elements ED-1, ED-2, and ED-3.

In FIG. 4, the base substrate BS may have a single-layered structure or a multi-layered structure. For example, the base substrate BS may include a first synthetic resin layer, an intermediate layer in a multi-layered or a single-layered structure, and a second synthetic resin layer, which may be stacked in that order. The intermediate layer may be referred to as a base barrier layer. The intermediate layer may include a silicon oxide (SiOₓ) layer, and an amorphous silicon (a-Si) layer disposed on the silicon oxide layer, but embodiments are limited thereto. For example, the intermediate layer may include at least one of a silicon oxide layer, a silicon nitride layer, a silicon oxynitride layer, and an amorphous silicon layer.

The first and second synthetic resin layers may each include a polyimide-based resin. In embodiments, the first and second synthetic resin layers may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, the term “a”-based resin may refer to a resin that includes a functional group of “a”.

The circuit layer DP-CL is disposed on the base substrate BS, and the circuit layer DP-CL may include transistors (not shown). The transistors (not shown) may each include a control electrode, an input electrode, and an output electrode. For example, the circuit layer DP-CL may include a switching transistor and a driving transistor in order to drive the light emitting elements ED-1, ED-2, and ED-3 of the display element layer DP-EL.

The light emitting regions PXA-R, PXA-G, and PXA-B may be arranged into groups according to the colors of light generated from the light emitting elements ED-1, ED-2, and ED-3. FIGS. 3 and 4 illustrate three light emitting regions PXA-R, PXA-G, and PXA-B, which respectively emit red light, green light, and blue light, as an example. For example, the display device DD may include the red light emitting region PXA-R, the green light emitting region PXA-G, and the blue light emitting region PXA-B that are separated from each other.

The display panel DP may include multiples of each of the light emitting elements ED-1, ED-2, and ED-3, which may emit light in different wavelength regions. The light emitting elements ED-1, ED-2, and ED-3 may emit light having colors that are different from each other. For example, the display panel DP may include a first light emitting element ED-1 that emits red light, a second light emitting element ED-2 that emits green light, and a third light emitting element ED-3 that emits blue light. However, embodiments are not limited thereto and the first to third light emitting elements ED-1, ED-2, and ED-3 may emit light in a same wavelength region, or at least one light emitting element may emit light in a wavelength region that is different from the remainder.

For example, the blue light emitting region PXA-B, the green light emitting region PXA-G, and the red light emitting region PXA-R of the display device DD may respectively correspond to the first light emitting element ED-1, the second light emitting element ED-2, and the third light emitting element ED-3.

The display device DD according to an embodiment may include light emitting elements ED-1, ED-2, and ED-3, and the light emitting elements ED-1, ED-2, and ED-3 may include emission layers EML-B EML-G, and EML-R which respectively include quantum dots QD-C1, QD-C2, and QD-C3.

A first emission layer EML-B of a first light-emitting element ED-1 may include a first quantum dot QD-C1. The first quantum dot QD-C1 may emit blue light that is a first light. A second emission layer EML-G of a second light-emitting element ED-2 and a third emission layer EML-R of a third light-emitting element ED-3 may respectively include a second quantum dot QD-C2 and a third quantum dot QD-C3. The second quantum dot QD-C2 and the third quantum dot QD-C3 may respectively emit green light that is a second light, and red light that is a third light.

In an embodiment, the first light may have a wavelength region in a range of about 410 nm to about 480 nm, the second light may have a wavelength region in a range of about 500 nm to about 570 nm, and the third light may have a wavelength region in a range of about 625 nm to about 675 nm.

In the specification, a quantum dot may be a crystal of a semiconductor compound. The quantum dot may emit light having various emission wavelengths depending on a size of crystal. The quantum dot may emit light having various emission wavelengths as an elemental ratio in the quantum dot compound is adjusted.

The quantum dot may have a diameter in a range of, for example, about 1 nm to about 10 nm.

The quantum dot may be synthesized by a wet chemical process, a metal organic chemical vapor deposition process, a molecular beam epitaxy process, a similar process thereto, or the like.

The wet chemical process is a method in which a precursor material is mixed with an organic solvent to grow quantum dot particle crystals. When the crystals grow, the organic solvent may further serve as a dispersant that is coordinated on the surface of the quantum dot crystals and may control the growth of the crystals. Thus, the wet chemical process may control the growth of quantum dot particles through a process which may be more readily performed than vapor deposition methods, such as metal organic chemical vapor deposition (MOCVD) or molecular beam epitaxy (MBE), and which is performed at low costs.

The quantum dots QD-C1, QD-C2, and QD-C3 included in the emission layer EML according to an embodiment may be nano crystal which may be a Group II-VI semiconductor compound, a Group III-V semiconductor compound, a Group III-VI semiconductor compound, a Group I-III-VI semiconductor compound, a Group IV-VI semiconductor compound, a Group IV element, a Group IV semiconductor compound, or a combination thereof.

Examples of a Group II-VI semiconductor compound may include: a binary compound selected from the group consisting of CdSe, CdTe, CdS, ZnS, ZnSe, ZnTe, ZnO, HgS, HgSe, HgTe, MgSe, MgS, and any combination thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any combination thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any combination thereof; and any combinations thereof. In an embodiment, a Group II-VI semiconductor compound may further include a Group I metal and/or a Group IV element. Examples of a Group I-II-VI compound may include CuSnS or CuZnS. Examples of a Group II-IV-VI compound may include ZnSnS, etc. Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and any combination thereof.

Examples of a Group III-VI semiconductor compound may include: a binary compound such as In₂S₃ or In₂Se₃, a ternary compound such as InGaS₃ or InGaSe₃, and any combination thereof.

Examples of a Group I-III-VI semiconductor compound may include: a ternary compound selected from the group consisting of AgInS, AgInS₂, CuInS, CulnS₂, AgGaS₂, CuGaS₂, CuGaO₂, AgGaO₂, AgAlO₂, and any combination thereof; or a quaternary compound such as AgInGaS₂ or CuInGaS₂.

Examples of a Group III-V semiconductor compound may include: a binary compound selected from the group consisting of GaN, GaP, GaAs, GaSb, AlN, AlP, AlAs, AlSb, InN, InP, InAs, InSb, and any combination thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any combination thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any combination thereof. In an embodiment, a Group III-V compound may further include a Group II element. Examples of a Group III-V semiconductor compound further including a Group II element, may include InZnP, etc.

Examples of a Group IV-VI semiconductor compound may include: a binary compound selected from the group consisting of SnS, SnSe, SnTe, PbS, PbSe, PbTe, and any combination thereof; a ternary compound selected from the group consisting of SnSeS, SnSeTe, SnSTe, PbSeS, PbSeTe, PbSTe, SnPbS, SnPbSe, SnPbTe, and any combination thereof; and a quaternary compound selected from the group consisting of SnPbSSe, SnPbSeTe, SnPbSTe, and any combination thereof.

Examples of a Group II-IV-V semiconductor compound may include a ternary compound selected from the group consisting of ZnSnP, ZnSnP₂, ZnSnAs₂, ZnGeP₂, ZnGeAs₂, CdSnP₂, CdGeP₂, and any combination thereof.

Examples of a Group IV element may include Si, Ge, and any combination thereof. Examples of a Group IV semiconductor compound may include a binary compound selected from the group consisting of SiC, SiGe, and any combination thereof.

Each element included in a compound, such as a binary compound, a ternary compound, or a quaternary compound, may be present in a particle at a uniform or at a non-uniform concentration distribution. For example, a formula of a quantum dot compound may indicate the elements that are included in the compounds, but an elemental ratio in the compound may vary. For example, AgInGaS₂ may indicate AgInₓGa₁₋ₓS₂ (where x is a real number between 0 and 1).

In an embodiment, the binary compound, the ternary compound, or the quaternary compound may be present in a particle at a uniform concentration distribution, or may be present in a particle at a partially different concentration distribution. In an embodiment, the quantum dot may have a core/shell structure in which a quantum dot surrounds another quantum dot. A quantum dot that has a core/shell structure may have a concentration gradient in which the concentration of an element that is present in the shell decreases toward the core.

In embodiments, the quantum dots QD-C1, QD-C2 and QD-C3 may have the above-described core/shell structure including a core containing nanocrystals and a shell surrounding the core. The shell of each of the quantum dots QD-C1, QD-C2, and QD-C3 may serve as a protection layer that prevents chemical deformation of the core to maintain semiconductor properties, and/or may serve as a charging layer that imparts electrophoretic properties to the quantum dot. The shell may be single-layered or multilayered. An example of the shell of the quantum dots QD-C1, QD-C2, and QD-C3 may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound such as MgAl₂O₄, CoFe₂O₄, NiFe₂O₄, or CoMn₂O₄, but embodiments not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dots QD-C1, QD-C2, and QD-C3 may each independently have a full width at half maximum (FWHM) of an emission wavelength spectrum less than or equal to about 45 nm. For example, the quantum dots QD-C1, QD-C2, and QD-C3 may each independently have a FWHM of an emission wavelength spectrum less than or equal to about 40 nm. For example, the quantum dots QD-C1, QD-C2, and QD-C3 may each independently have a FWHM of an emission wavelength spectrum less than or equal to about 30 nm. When the FWHM of an emission wavelength spectrum of the quantum dot QD-C falls within any of the above ranges, color purity or color reproducibility may be improved. Light emitted through quantum dots QD-C1, QD-C2, and QD-C3 may be emitted in all directions, so that a wide viewing angle may be improved.

The form of each of the quantum dots QD-C1, QD-C2, and QD-C3 is not particularly limited and may be any form used in the related art. For example, a quantum dot may be in a spherical shape, a pyramidal shape, a multi-arm shape, or a cubic shape, or the quantum dots QD-C1, QD-C2, and QD-C3 may each be in the form of nanoparticles, nanotubes, nanowires, nanofibers, nanoplate particles, etc.

With regard to quantum dots QD-C1, QD-C2, and QD-C3, as a size of the quantum dot is adjusted or an elemental ratio in the quantum dot compound is adjusted, it is possible to control the energy band gap, and thus light in various wavelength ranges may be obtained from a quantum dot emission layer. Therefore, by using the quantum dots as described above, for example, using different sizes of quantum dots or different elemental ratios in the quantum dot compound, a light emitting element that emits light in various wavelengths, may be implemented. For example, the adjustment of the size of the quantum dots QD-C1, QD-C2, and QD-C3 or the adjustment of an elemental ratio in a quantum dot compound may be selected to emit red light, green light, and/or blue light. In an embodiment, the quantum dots QD-C1, QD-C2, and QD-C3 may be configured to emit white light by combining various colors of light.

The quantum dots QD-C1, QD-C2, and QD-C3 may control the color of emitted light according to a particle size thereof, and thus the quantum dots QD-C1, QD-C2, and QD-C3 can have various luminescent colors such as blue, red, and green. As the particle size of the quantum dots QD-C1, QD-C2, and QD-C3 becomes smaller, the quantum dots QD1, QD2, and QD3 may emit light in a shorter wavelength region. For example, in the quantum dots QD-C1, QD-C2, and QD-C3 having a same core, the particle size of a quantum dot emitting green light may be smaller than the particle size of a quantum dot emitting red light. In an embodiment, in the quantum dots QD-C1, QD-C2, and QD-C3 having a same core, the particle size of a quantum dot emitting blue light may be smaller than the particle size of a quantum dot emitting green light. However, embodiments are not limited thereto, and even in the quantum dots QD-C1, QD-C2, and QD-C3 having a same core, the particle size may be adjusted according to the materials used to form the quantum dots QD-C1, QD-C2, and QD-C3 and according to the thickness of a shell.

When quantum dots QD-C1, QD-C2, and QD-C3 have various luminescent colors such as blue, red, and green, the quantum dots QD-C1, QD-C2, and QD-C3 that have different luminescent colors may have different core materials.

In an embodiment, the first to third quantum dots QD-C1, QD-C2, and QD-C3 may have different diameters. For example, the first quantum dot QD-C1 used in the first light emitting element ED-1 emitting light in a relatively shorter wavelength range may have a relatively smaller average diameter than the second quantum dot QD-C2 of the second light emitting element ED-2 and the third quantum dot QD-C3 of the third light emitting element ED-3 each emitting light in a relatively longer wavelength region.

In the specification, the term “average diameter” may refer to the arithmetic mean of the diameters of the quantum dot particles. The diameter of a quantum dot particle may be an average value of a cross-sectional width of the quantum dot particle.

The relationship of the average diameters of the first to third quantum dots QD-C1, QD-C2 and QD-C3 is not limited to the above examples. For example, FIG. 4 illustrates that the first to third quantum dots QD-C1, QD-C2, and QD-C3 may be similar in size to one another, but embodiments are not limited thereto. Although not shown in the drawings, in an embodiment, the first to third quantum dots QD-C1, QD-C2, and QD-C3 included in the light emitting elements ED-1, ED-2, and ED-3 may be different in size. For example, an average diameter of two quantum dots selected from the first to third quantum dots QD-C1, QD-C2, and QD-C3 may be similar, and the remainder may have a different diameter.

In an embodiment, in the light emitting elements ED-1, ED-2, and ED-3, emission layers EML-B, EML-G, and EML-R each may include a host and a dopant. In an embodiment, the emission layers EML-B, EML-G, and EML-R may include quantum dots QD-C1, QD-C2, and QD-C3 as dopant materials. In an embodiment, the emission layers EML-B, EML-G, and EML-R may further include host materials. In an embodiment, in the light emitting elements ED-1, ED-2, and ED-3, emission layers EML-B, EML-G, and EML-R may emit fluorescence. For example, quantum dots QD-C1, QD-C2, and QD-C3 may be used as a fluorescent dopant material.

Although not illustrated in the drawings, the first to third quantum dots QD-C1, QD-C2, and QD-C3 may each have ligands bonded to a surface thereof, for the improvement of dispersibility.

In the display device DD according to an embodiment, as illustrated in FIGS. 3 and 4, the light emitting regions PXA-B, PXA-G, and PXA-R each may have a different area from one another. The areas may be areas in a plan view that are defined by the first direction DR1 and the second direction DR2.

The light emitting regions PXA-R, PXA-G, and PXA-B may have different areas according to a color emitted from the emission layers EML-B, EML-G, and EML-R of the light emitting elements ED-1, ED-2, and ED-3. The blue light emitting region PXA-B of the first light emitting element ED-1, which emits blue light, may have the largest area, and the green light emitting region PXA-G of the second light emitting element ED-2, which emits green light, may have the smallest area. However, embodiments are not limited thereto, and the light emitting regions PXA-R, PXA-G, and PXA-B may emit light having a different color other than red light, green light, and blue light. In an embodiment, the light emitting regions PXA-R, PXA-G, and PXA-B may have a same area as one another, or the light emitting regions PXA-R, PXA-G, and PXA-B may have areas that are in different relative proportions than what is illustrated in FIG. 3.

The light emitting regions PXA-B, PXA-G, and PXA-R may be separated from each other by a pixel defining film PDL. The peripheral emitting regions NPXA may be regions between the adjacent light emitting regions PXA-B, PXA-G, and PXA-R, which may correspond to the pixel defining film PDL. In the specification, the light emitting regions PXA-B, PXA-G, and PXA-R may each correspond to a pixel.

In FIG. 4, the display element layer DP-EL may include the pixel defining film PDL and the first to third light emitting elements ED-1, ED-2, and ED-3. Openings OH may be defined in the pixel defining film PDL.

The pixel defining film PDL may separate the light emitting elements ED-1, ED-2, and ED-3 from each other. The emission layers EML-B, EML-G, and EML-R of the light emitting elements ED-1, ED-2, and ED-3 may be disposed in the openings OH defined by the pixel defining PDL and separated from each other. In an embodiment, the first emission layer EML-B of the first light emitting element ED-1 may be disposed in a first opening OH1, the second emission layer EML-G of the second light emitting element ED-2 may be disposed in a second opening OH2, and the third emission layer EML-R of the third light emitting element ED-3 may be disposed in a third opening OH3.

The pixel defining film PDL may include a polymer resin. For example, the pixel defining film PDL may include a polyacrylate-based resin or a polyimide-based resin. In an embodiment, the pixel defining film PDL may further include an inorganic material in addition to the polymer resin. The pixel defining film PDL may include a light absorbing material, a black pigment, or a black dye. The pixel defining film PDL that includes a black pigment or a black dye may form a black pixel definition layer. In forming the pixel defining film PDL, carbon black, etc. may be used as the black pigment or the black dye, but embodiments not limited thereto.

The pixel defining film PDL may include inorganic materials. For example, the pixel defining film PDL may include silicon nitride (SiNₓ), silicon oxide (SiOₓ), silicon nitrate (SiOₓN_{y}), silicon oxynitride (SiNₓO_{y}) etc. The pixel defining film PDL may define the light emitting regions PXA-B, PXA-G, and PXA-R. The light emitting regions PXA-B, PXA-G, and PXA-R and the peripheral regions NPXA may be separated by the pixel defining films PDL.

The light emitting elements ED-1, ED-2, and ED-3 may each include a first electrode EL1, hole transport regions HTR-1, HTR-2, and HTR-3 disposed on the first electrode EL1, emission layers EML-B, EML-G, and EML-R respectively disposed on hole transport regions HTR-1, HTR-2, and HTR-3, electron transport regions ETR-1, ETR-2, and ETR-3 respectively disposed on the emission layers EML-B, EML-G, and EML-R, and a second electrode EL2 disposed on the electron transport regions ETR-1, ETR-2, and ETR-3.

The hole transport regions HTR-1, HTR-2, and HTR-3 and the electron transport regions ETR-1, ETR-2, and ETR-3 respectively included in the light emitting elements ED-1, ED-2, and ED-3, may be disposed and separated in the openings OH1, OH2, and OH3 defined in the pixel defining film PDL.

For example, a first hole transport region HTR-1 and a first electron transport region ETR-1 included in the first light emitting element ED-1 may be disposed adjacent to the first emission layer EML-B, and may be patterned in a first opening OH1 in which the first emission layer EML-B is disposed. A second hole transport region HTR-2 and a second electron transport region ETR-2 included in the second light emitting element ED-2 may be disposed adjacent to the second emission layer EML-G, and may be patterned in a second opening OH2 in which the second emission layer EML-G is disposed. A third hole transport region HTR-3 and a third electron transport region ETR-3 included in the third light emitting element ED-3 may be disposed adjacent to the third emission layer EML-R, and may be patterned in a third opening OH3 in which the third emission layer EML-R is disposed. However, embodiments are not limited thereto, and the hole transport regions HTR-1, HTR-2, and HTR-3 and the electron transport regions ETR-1, ETR-2, and ETR-3 may be provided as a common layer disposed in pixel regions PXA-B, PXA-G, and PXA-R and the peripheral regions NPXA.

In an embodiment, the hole transport regions HTR-1, HTR-2, and HTR-3 and the electron transport regions ETR-1, ETR-2, and ETR-3 may be respectively provided in the openings OH1, OH2, and OH3, defined in the pixel defining film PDL through a printing process.

The encapsulation layer TFE may cover the light emitting elements ED-1, ED-2, and ED-3. The encapsulation layer TFE may seal the display element layer DP-EL. The encapsulation layer TFE may be a thin film encapsulation layer. The encapsulation layer TFE may include a single layer or may include multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-EL from moisture and/or oxygen, and the encapsulation-organic film may protect the display element layer DP-EL from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH1, OH2, and OH3.

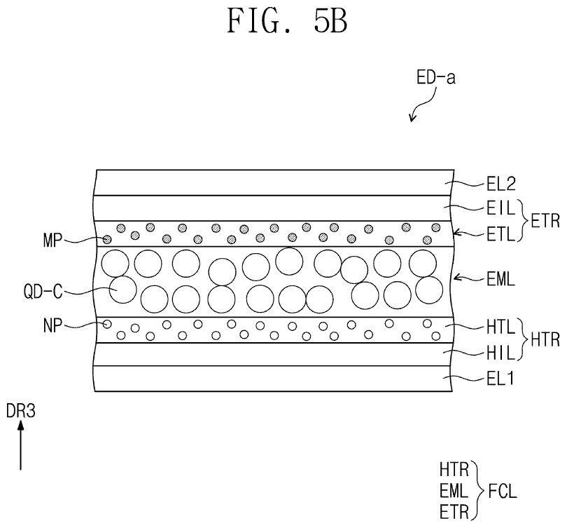

In the display device DD illustrated in FIG. 5, although the thicknesses of the emission layers EML-B, EML-G, and EML-R of the first to third light emitting elements ED-1, ED-2, and ED-3 are illustrated to be similar to one another, embodiments are not limited thereto. For example, in an embodiment, the thicknesses of the emission layers EML-B, EML-G, and EML-R of the first to third light emitting elements ED-1, ED-2, and ED-3 may be different from one another. In an embodiment, a thickness of each of the hole transport regions HTR-1, HTR-2, and HTR-3 and the electron transport regions ETR-1, ETR-2, and ETR-3 of the first to third light emitting elements ED-1, ED-2, and ED-3 may also be different from one another.

Referring to FIG. 3, the blue light emitting regions PXA-B and the red light emitting regions PXA-R may be alternately arranged along the first direction DR1 to constitute a first group PXG1. The green light emitting regions PXA-G may be arranged along the first direction DR1 to constitute a second group PXG2. The first group PXG1 may be spaced apart from the second group PXG2 along the second direction DR2. Multiples of each of the first group PXG1 and the second group PXG2 may be provided. The first groups PXG1 and the second groups PXG2 may be alternately arranged along the second direction DR2.

A red light emitting region PXA-R may be spaced apart from a green light emitting region PXA-G along a fourth direction DR4. A blue light emitting region PXA-B may be spaced apart from a green light emitting region PXA-G along a fifth direction DR5. The fourth direction DR4 may be a direction between the first direction DR1 and the second direction DR2. The fifth direction DR5 may cross the fourth direction DR4 and may be inclined toward the second direction DR2.

In an embodiment, an arrangement of the light emitting regions PXA-B, PXA-G, and PXA-R illustrated in FIG. 3 may be referred to as a pentile structure (for example, a PenTile® configuration). The arrangement of the light emitting regions PXA-R, PXA-G, and PXA-B is not limited to the arrangement illustrated in FIG. 3. For example, in the light emitting regions PXA-R, PXA-G, and PXA-B, a red light emitting region PXA-R, a green light emitting region PXA-G, and a blue light emitting region PXA-B may be arranged in this order as a repeating sequence along the first direction DR1. In an embodiment, the shapes of each of the light emitting regions PXA-R, PXA-G, and PXA-B in a plan view are not limited to what is illustrated in the drawings, and may be defined as shapes that are different from what is illustrated.

Referring to FIG. 4, the display device DD according to an embodiment may further include an optical member PP. The optical member PP may block external light outside the display device DD to the display panel DP. The optical member PP may block a portion of external light. The optical member PP may prevent reflection by minimizing reflection of an external light.

In an embodiment illustrated in FIG. 4, the optical member PP may include a base layer BL and a color filter layer CFL. The display device DD according to an embodiment may further include the color filter layer CFL disposed on the light emitting elements ED-1, ED-2, and ED-3 of the display panel DP.

The base layer BL may provide a base surface on which the color filter layer CFL is disposed. The base layer BL may be a glass substrate, a metal substrate, a plastic substrate, etc. However, embodiments are not limited thereto, and the base layer BL may include an inorganic layer, an organic layer, or a composite material layer.

The color filter layer CFL may include first to third filters CF-B, CF-G, and CF-R. The first to third filters CF-B, CF-G, and CF-R may be disposed to respectively correspond to the first to third light emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed so that they respectively correspond to the first to third pixel regions PXA-R, PXA-B, and PXA-G.

The first to third filters CF-B, CF-G, and CF-R may each include a polymeric photosensitive resin, and a pigment or a dye. The first filter CF-B may include a blue pigment or a blue dye, the second filter CF-G may include a green pigment or a green dye, and the third filter CF-R may include a red pigment or a red dye. However, embodiments are not limited thereto, and the first filter CF-B may not include a pigment or a dye. The first filter CF-B may include a polymeric photosensitive resin, but may not include a pigment or a dye. The first filter CF-B may be transparent. The first filter CF-B may be formed of a transparent photosensitive resin.

The color filter layer CFL may further include a buffer layer BFL. For example, the buffer layer BFL may serve as a protective layer that protects the first to third filters CF-B, CF-G, and CF-R. The buffer layer BFL may be an inorganic material layer that includes at least one of silicon nitride, silicon oxide, and silicon oxynitride. The buffer layer BFL may be formed of a single layer or of multiple layers.

In an embodiment, the second filter CF-G and the third filter CF-R may each be a yellow filter. The second filter CF-G and the third filter CF-R may not be provided as separate filters, and may be provided as a unitary filter.

In an embodiment illustrated in FIG. 4, the first filter CF-B of the color filter layer CFL is illustrated to overlap the second filter CF-G and the third filter CF-R, but embodiments are not limited thereto. For example, the first to third filters CF-B, CF-G, and CF-R may be separated by a light shielding part (not shown) and may not overlap one another. In an embodiment, the first to third filters CF-B, CF-G, and CF-R may be disposed to respectively correspond to the blue light emitting region PXA-B, the green light emitting region PXA-G, and the red light emitting region PXA-R. In an embodiment, in the display device DD, the color filter layer CFL may be omitted.

Although not shown in the drawings, the color filter layer CFL may further include a light shielding part (not shown). The light shielding part (not shown) may be a black matrix. The light shielding part (not shown) may include an organic light shielding material or an inorganic light shielding material each including a black pigment or dye. The light shielding part may prevent light leakage, and may separate boundaries between the adjacent filters CF-B, CF-G, and CF-R.

Although not shown in FIG. 4, a display device DD according to an embodiment may include a polarizing layer (not shown) as the optical member PP instead of the color filter layer CFL. The polarizing layer (not shown) may block light reflected at the display panel DP from the outside. The polarizing layer (not shown) may block a part of the external light.

In an embodiment, the polarizing layer (not shown) may reduce light reflected at the display panel DP from an external light. For example, the polarizing layer (not shown) may block reflected light where an external light the outside the display device DD is incident to the display panel DP and exits again through the polarizing layer (not shown). The polarizing layer (not shown) may be a circular polarizer having a reflection preventing function or the polarizing layer may include a linear polarizer and a λ/4 phase retarder. The polarizing layer (not shown) may be disposed on the base layer BL or the polarizing layer (not shown) may be disposed under the base layer BL.

FIG. 5A is a schematic cross-sectional view of a light emitting element according to an embodiment. At least one of the first to third light emitting elements ED-1, ED-2, and ED-3 illustrated in FIG. 4 may each independently have a structure according to the light emitting element ED described with reference to FIG. 5A.

Referring to FIG. 5A, the light emitting element ED includes a first electrode EL1, a functional layer FCL, and a second electrode EL2, which may be stacked in that order. The functional layer FCL may include a hole transport region HTR, an emission layer EML, and an electron transport region ETR.

In the light emitting element ED according to an embodiment, the first electrode EL1 may have conductivity. The first electrode EL1 may be formed of a metal alloy or a conductive compound. The first electrode EL1 may be an anode. The first electrode EL1 may be a pixel electrode.

In the light emitting element ED according to an embodiment, the first electrode EL1 may be a reflective electrode. However, embodiments are not limited thereto. For example, the first electrode EL1 may be a transmissive electrode or a transflective electrode. When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In an embodiment, the first electrode EL1 may have a multilayered structure including a reflective layer or a transflective layer formed of the above-described material, and a transmissive conductive layer formed of indium tin oxide (ITO), indium zinc oxide (IZO), zinc oxide (ZnO), indium tin zinc oxide (ITZO) and the like. For example, the first electrode EL1 may include a multilayered metal layer, such as a stacked structure of ITO/Ag/ITO.

The hole transport region HTR may be provided on the first electrode EL1. The hole transport region HTR may include a hole injection layer HIL, a hole transport layer HTL, etc. In an embodiment, the hole transport region HTR may further include at least one of a hole buffer layer (not shown) and an electron blocking layer EBL, in addition to a hole injection layer HIL and a hole transport layer HTL. The hole buffer layer (not shown) may compensate for a resonance distance according to a wavelength of light emitted from the emission layer EML, and may thus increase luminous efficiency. Materials which may be included in the hole transport region HTR may be used as materials included in the hole buffer layer (not shown). The electron blocking layer EBL may prevent electron injection from an electron transport region ETR to a hole transport region HTR.

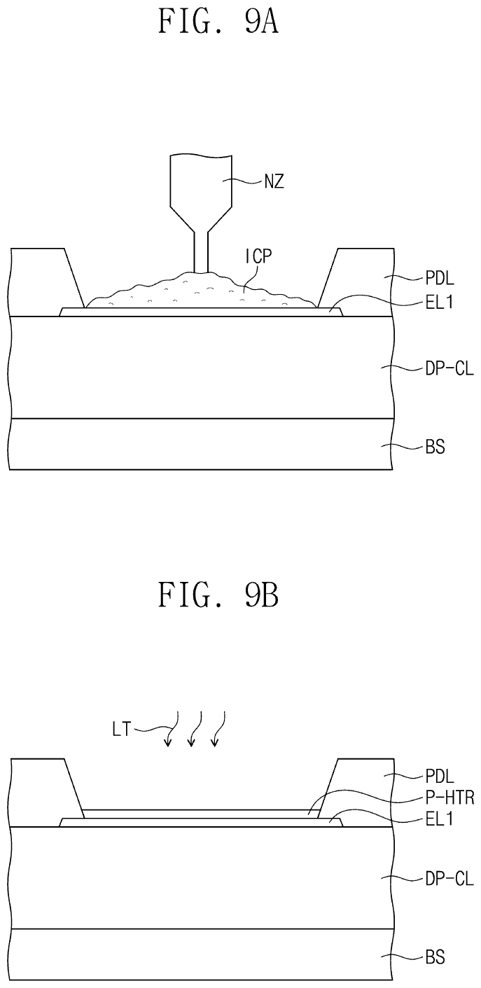

The hole transport region HTR may include nanoparticles NP. In the light emitting element ED according to an embodiment, the nanoparticles NP included in the hole transport region HTR may each include a core CO (see FIG. 8) that includes nickel (Ni) and a first metal. The core may include a metal oxide in which the first metal is doped into nickel (Ni) oxide. In an embodiment, the first metal may be zinc (Zn), tin (Sn), titanium (Ti), copper (Cu), magnesium (Mg), or chromium (Cr). In an embodiment, the nanoparticles NP may each further include ligands LG (see FIG. 8) bonded to a surface of the core CO. A detailed description of the nanoparticles NP will be described later.

The hole transport region HTR may be formed from an ink composition ICP (see FIG. 8) according to an embodiment, which will be described later. For example, the hole transport region HTR may be formed from the ink composition ICP (see FIG. 8) including the nanoparticles NP and a solvent CV. In the specification, the ink composition ICP (see FIG. 8) containing the nanoparticles NP may be referred to as a “hole transport composition.”

When an organic material is used as a hole transport region material in a quantum dot-based light emitting element, the organic material may deteriorate upon exposure to air, and the organic layer may significantly deteriorate at a temperature equal to or greater than a certain temperature, thereby degrading the characteristics of the element. In an embodiment, a high temperature process, for example, a baking process, may be performed to dry the solvent in a quantum dot composition applied during the formation of the emission layer, which may deteriorate an organic layer that is disposed underneath. To prevent or avoid such deterioration, a method for introducing inorganic material-based metal oxide nanoparticles into the hole transport region may be applied.

In embodiments, the nanoparticles NP each including the core doped with the first metal in the nickel (Ni) oxide may be introduced into the hole transport region HTR, so that even if a high-temperature process is performed when manufacturing a quantum dot-based element, there is little risk of deterioration compared to an organic material, thereby exhibiting high process stability. In an embodiment, in the nanoparticles NP, a band energy of the core CO may be appropriately adjusted by the first metal as a dopant, and thus hole injection and transport characteristics may be improved, thereby contributing to charge balance in the emission layer. Accordingly, the light emitting element ED including the hole transport region HTR including the nanoparticles NP may secure excellent process stability, and may achieve high luminous efficiency and long service life. In the specification, the term “band energy” may refer to a valence band and a conduction band of inorganic particles.

Referring again to FIG. 5A, the hole transport region HTR may have a structure consisting of a layer consisting of a single material, a structure consisting of a layer including different materials, or a structure including multiple layers including different materials. For example, the hole transport region HTR may have a single-layer structure formed of different materials, or may have a structure in which a hole injection layer HIL/hole transport layer HTL, a hole injection layer HIL/hole transport layer HTL/hole buffer layer (not shown), a hole injection layer HIL/hole buffer layer (not shown), a hole transport layer HTL/hole buffer layer (not shown), or a hole injection layer HIL/hole transport layer HTL/electron blocking layer EBL are stacked in its respective stated order from the first electrode EL1, but embodiments are not limited thereto.

When the hole transport region HTR has a structure including multiple layers, at least one of the layers may include the nanoparticles NP according to an embodiment. For example, when the hole transport region HTR has a structure including multiple layers, at least one of the layers may be formed from an ink composition ICP (see FIG. 8), which will be described below. For example, as illustrated in FIG. 5A, the hole transport region HTR may include a hole injection layer HIL disposed on the first electrode EL1, and a hole transport layer HTL disposed on the hole injection layer HIL, and the hole transport layer HTL may include the nanoparticles NP according to an embodiment. Although not shown in FIG. 5A, in another embodiment, the hole transport layer HTL and the hole injection layer HIL may each include the nanoparticles NP.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method. In an embodiment, the electron transport region ETR may be formed by inkjet printing.

In an embodiment, the hole transport region HTR may further include an inorganic material or an organic material of the related art.

The hole injection layer HIL may include, for example, a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine](m-MTDATA), 4,4′,4″-tris(N,N-diphenylamino)triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N-diphenyl-benzidine (NPD), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HAT-CN), etc.

The hole transport layer HTL may further include materials of the related art. For example, the hole transport layer HTL may further include carbazole derivatives such as N-phenyl carbazole and polyvinyl carbazole, fluorine derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), N,N-di(1-naphtalene-1-yl)-N,N-diphenyl-benzidine (NPD), 4,4′-cyclohexylidene bis[N,N-bis(4-methylphenyl]benzenamine](TAPC), 4,4′-bis[N,N′ (3-tolyl)amino]-3,3′-dimethylbiphenyl (HMTPD), 1,3-bis(N-carbazolyl)benzene (mCP), etc.

The hole transport region HTR may have a thickness of in a range of about 5 nm to about 1,500 nm. For example, the hole transport region HRT may have a thickness in a range of about 10 nm to about 500 nm. The hole injection layer HIL may have a thickness in a range of, for example, about 3 nm to about 200 nm, and the hole transport layer HTL may have a thickness in a range of about 3 nm to about 100 nm. For example, the electron blocking layer EBL may have a thickness in a range of about 1 nm to about 100 nm. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The emission layer EML may be provided on the hole transport region HTR. The emission layer EML may, for example, have a thickness in a range of about 10 nm to about 100 nm. For example, the emission layer EML may have a thickness in a range of about 10 nm to about 30 nm. The emission layer EML may have a structure consisting of a layer consisting of a single material, a structure consisting of a layer including different materials, or a structure including multiple layers including different materials. In the light emitting element ED according to an embodiment, the emission layer EML may include a quantum dot QD-C. The quantum dot QD-C may be the same as one of the first to third quantum dots QD-C1, QD-C2, and QD-C3 in FIG. 4.

The emission layer EML may be formed by using various methods such as a vacuum deposition method, a spin coating method, a casting method, a Langmuir-Blodgett (LB) method, an inject printing method, a laser printing method, and a laser induced thermal imaging (LITI) method. In an embodiment, the emission layer EML may be formed by providing a quantum dot composition including the quantum dot QD-C by an inkjet printing method.

In the light emitting element ED according to an embodiment, an electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of the electron injection layer EIL or the electron transport layer ETL, and may have a single layer structure formed of an electron injection material and an electron transport material. In an embodiment, the electron transport region ETR may have a structure including different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the electron transport region ETR may include an inorganic material or an organic material of the related art.

When the electron transport region ETR includes the electron transport layer ETL, the electron transport region ETR may include an anthracene-based compound. However, embodiments are not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3-(pyridin-3-yl) biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), beryllium bis(benzoquinolin-10-olate) (Bebq₂), 9,10-di(naphthalene-2-yl) anthracene (ADN), or a mixture thereof. A thickness of the electron transport layer ETL may be in a range of about 10 nm to about 100 nm. For example, the thickness of the electron transport layer ETL may be in a range of about 15 nm to about 50 nm. When the thickness of the electron transport layer ETL satisfies any of the above-described ranges, satisfactory electron transport properties may be obtained without substantial increase of a driving voltage.

When the electron transport region ETR includes an electron injection layer EIL, the electron transport region ETR may include: a metal halide such as LiF, NaCl, CsF, RbCl, and RbI; a lanthanide metal such as Yb; a metal oxide such as Li₂O and BaO, or lithium quinolate (LiQ), etc., but embodiments are not limited thereto. The electron injection layer EIL may also be formed of a mixture of an electron transport material and an insulating organometallic salt. For example, the organometallic salt may include a metal acetate, a metal benzoate, a metal acetoacetate, a metal acetylacetonate, or a metal stearate. A thickness of the electron injection layer EIL may be in a range of about 0.1 nm to about 10 nm. For example, the thickness of the electron injection layer EIL may be in a range of about 0.3 nm to about 9 nm. When the thickness of the electron injection layer EIL satisfies any of the above described ranges, satisfactory electron injection properties may be obtained without inducing substantial increase of a driving voltage.

The electron transport region ETR may include a hole blocking layer HBL as described above. The hole blocking layer HBL may include, for example, at least one of 2,9-dimethyl-4,7-diphenyl-1,10-phenanthroline (BCP), and 4,7-diphenyl-1,10-phenanthroline (Bphen), but embodiments are not limited thereto.

The second electrode EL2 may be provided on the electron transport region ETR. The second electrode EL2 may be a common electrode or a negative electrode. The second electrode EL2 may be a transmissive electrode, a transflective electrode or a reflective electrode. When the second electrode EL2 is a transmissive electrode, the second electrode EL2 may include a transparent metal oxide, for example, indium tin oxide (ITO), indium zinc oxide (IZO) zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In an embodiment, the first electrode EL1 may have a multilayer structure including a reflective layer or a transflective layer formed of the above-described materials, and a transparent conductive layer formed of ITO, IZO, ZnO, ITZO, etc.

Although not shown in the drawings, the second electrode EL2 may be electrically connected to an auxiliary electrode. When the second electrode EL2 is electrically connected to an auxiliary electrode, resistance of the second electrode EL2 may decrease.

FIG. 5B is a schematic cross-sectional view of a light emitting element according to an embodiment. FIG. 5B illustrates a light emitting element ED-a having a structure that is different from the light emitting element ED shown in FIG. 5A. At least one of the first to third light emitting elements ED-1, ED-2, and ED-3 illustrated in FIG. 4 may each independently have a structure according to the light emitting element ED-a described with reference to FIG. 5B. In the description of FIG. 5B, features that have been explained with reference to FIGS. 1 to 5A will not be explained again, and the differing features will be described.

In comparison to the light emitting element ED illustrated in FIG. 5A, the light emitting element ED-a illustrated in FIG. 5B is different from the light emitting element ED at least in that the electron transport region ETR may include the inorganic particles MP.

In an embodiment, the inorganic particles MP may include a metal oxide or a metalloid oxide that includes silicon, aluminum, zinc, indium, gallium, yttrium, germanium, scandium, titanium, tantalum, hafnium, zirconium, cerium, molybdenum, nickel, chromium, iron, niobium, tungsten, tin, copper, or any mixture thereof, but embodiments are not limited thereto.

In an embodiment, the inorganic particles MP may include at least one of zinc oxide and tin oxide. The type of zinc oxide is not limited, and may be ZnO, which may be doped with Sn, Mg, or Ca. The tin oxide may be SnO, SnO₂, or any combination thereof.

In an embodiment, the inorganic particles MP may include at least one of ZnO, ZnSnO, ZnMgO, SnO₂, and ZnGaO.

The electron transport region ETR may be formed of an electron transport composition containing inorganic particles MP. For example, the electron transport region ETR may be formed of an electron transport composition that includes the inorganic particles MP and a solvent. The solvent for the electron transport composition may be the same as described with respect to the solvent of the ink composition ICP, which will be explained below.

In order to improve the luminous efficiency and service life characteristics of the quantum dot light emitting element, a method for introducing an inorganic metal oxide into the electron transport region may be used. When the electron transport region is formed of a composition that includes the inorganic metal oxide in the quantum dot light emitting element, a high-temperature process may be used for drying the solvent in the composition. When the hole transport region HTR disposed in the lower portion is formed of an organic material, the organic material included in the hole transport region may deteriorate in a high-temperature process, and thus efficiency and service life of the light emitting element may decrease. In embodiments, the nanoparticles NP each containing the core doped with the first metal in the nickel (Ni) oxide may be introduced into the hole transport region HTR, so that even if a high-temperature process is performed, there is little risk of deterioration compared to an organic material, thereby exhibiting high process stability. In an embodiment, a band energy of the core may be appropriately adjusted by the first metal as a dopant, and thus hole injection and transport characteristics may be improved, thereby contributing to charge balance in the emission layer. Accordingly, the light emitting element ED including the hole transport region HTR that includes the nanoparticles NP may secure excellent process stability, and may achieve high luminous efficiency and long service life.

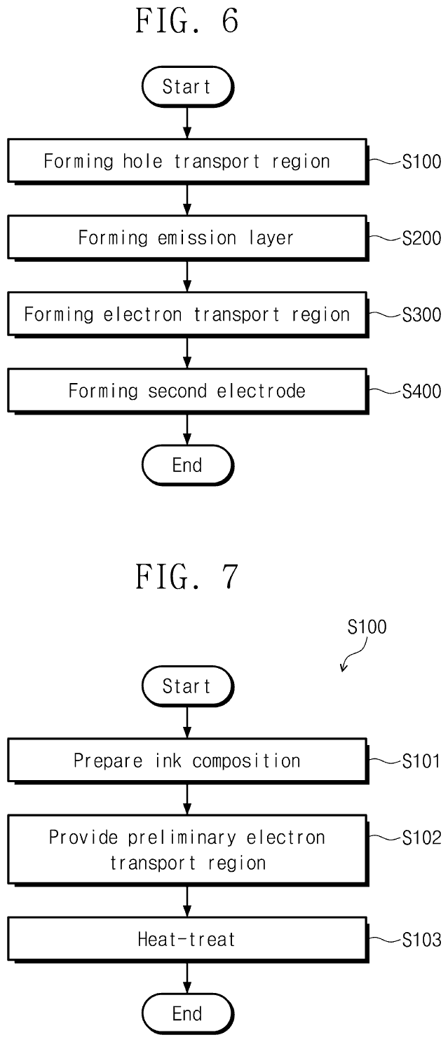

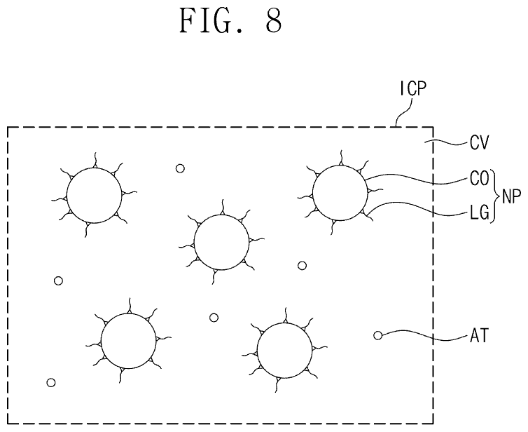

FIG. 6 is a flowchart of a method for manufacturing a light emitting element according to an embodiment. FIG. 7 is a flowchart of a divided step of forming a hole transport region (S100) according to an embodiment.

Referring to FIG. 6, a method for manufacturing a light emitting element includes forming a step of a hole transport region on a first electrode (S100), a step of forming an emission layer on the hole transport region (S200), a step of forming an electron transport region on the emission layer (S300), and a step of forming a second electrode on the electron transport region (S400).

Referring to FIG. 7, the step of forming the hole transport region (S100) according to an embodiment includes a step of preparing an ink composition (S101), a step of providing a preliminary hole transport region (S102), and a step of heat-treating the preliminary hole transport region (S103).

FIG. 8 is a schematic cross-sectional view of an ink composition ICP according to an embodiment. The ink composition ICP according to an embodiment may be a material for forming a hole transport region of a light emitting element. However, embodiments are not limited thereto, and the ink composition ICP may be a material for forming any layer included in the electron transport region ETR or in an emission layer EML of the light emitting element.

Referring to FIG. 8, the ink composition ICP according to an embodiment may include nanoparticles NP and a solvent CV. The nanoparticles NP may each include a core CO and ligands LG bonded to a surface of the core CO.

The core CO may include a metal oxide including nickel (Ni) and a first metal. The core CO may be a metal oxide in which the first metal is doped into nickel (Ni) oxide. In an embodiment, the first metal may be zinc (Zn), tin (Sn), titanium (Ti), copper (Cu), magnesium (Mg), or chromium (Cr). For example, the first metal may be zinc (Zn). The core CO may be formed by replacing nickel (Ni) ions with the first metal in NiO, and may exhibit improved stability and excellent electrical and optical characteristics. The first metal may be doped into a metal oxide containing nickel (Ni) to control hole mobility of the nickel oxide and may improve the chemical stability of the nanoparticles NP. Accordingly, the light emitting element ED including the hole transport region HTR formed of the ink composition ICP according to an embodiment may secure excellent process stability, and may achieve high luminous efficiency and long service life.

### In an Embodiment, the Core CO May be Represented by Formula 1:

Ni₁₋ₓMₓO [Formula 1]

In Formula 1, M may be Zn, Sn, Ti, Cu, Mg, or Cr. In an embodiment, M may be Zn.

In Formula 1, x may satisfy 0<x<1. In an embodiment, x may satisfy 0.01≤x<0.03. When x is greater than or equal to about 0.03, some electrons in the emission layer EML may leak into the hole transport region due to over-doping of the first metal, and thus the element efficiency may deteriorate. When x is less than 0.01, charge imbalance due to deterioration of hole injection characteristics may be induced, thereby deteriorating element characteristics. In Formula 1, when x satisfies any of the above-described ranges, optimal hole injection characteristics may be exhibited, and thus the luminous efficiency and element service life characteristics of the light emitting element ED may be further improved.

The nanoparticles NP may further include ligands LG bonded to a surface of the core CO. The ligands LG may improve the stability of the core CO to prevent an adverse reaction by oxygen, moisture, or the like, and may increase a distance between adjacent cores CO to prevent aggregation of the nanoparticles NP.

In an embodiment, the ligands LG may include a head portion, a linking portion linked to the head portion, and a tail portion linked to the linking portion. The head portion may be bonded to a surface of the core CO. The ligands LG may be bonded to a provided on the surface of the core CO. When the head portion includes a single functional group to be bonded to the surface of the core CO, the ligands LG may be monodentate ligands. When the head portion includes two functional groups to be bonded to the surface of the core CO, the ligands LG may be bidentate ligands. The head portion may include a functional group to be bonded to the surface of the core CO, so that the ligands LG may effectively bond to the core CO.

The head portion may be an electron donor head portion. In an embodiment, the head portion may be any one of a hydroxy group, a thiol group, an amine group, a carboxylic acid group, a dithioacid group, a phosphine group, and a catechol group.

The ligands LG may include a tail portion. The tail portion may be linked to the head portion. In an embodiment, the head portion may be bonded to a surface of the core CO, and the tail portion may be exposed to the outside of the nanoparticle NP. In an embodiment, the tail portion may include a hydroxy group, a thiol group, a substituted or unsubstituted oxy group, a substituted or unsubstituted thio group, a substituted or unsubstituted (meth)acrylate group, a substituted or unsubstituted alkyl group having 1 to 30 carbon atoms, or a substituted or unsubstituted alkenyl group having 2 to 30 carbon atoms.

In an embodiment, the ligands LG may include a 2-methoxyethoxy group. The tail portion of the ligand LG may include a 2-methoxyethoxy group. The 2-methoxyethoxy group may increase dispersibility of the core CO when the core CO is dispersed in the solvent CV. In the specification, the term “2-methoxyethoxy group” may mean a group represented by *—OCH₂CH₂OCH₃.

The ligand LG may contain a linking portion. The linking portion of the ligand LG may be linked to the head portion. The linking portion may link the head portion and the tail portion. For example, the ligand LG may include the head portion, the linking portion, and the tail portion, and the linking portion may be linked to the head portion, and the tail portion may be linked to the linking portion. In an embodiment, the linking portion may be a substituted or unsubstituted alkylene group having 1 to 30 carbon atoms, a substituted or unsubstituted alkenylene group having 2 to 30 carbon atoms, a substituted or unsubstituted arylene group having 6 to 30 ring-forming carbon atoms, or a substituted or unsubstituted heteroarylene group having 2 to 30 ring-forming carbon atoms. For example, the linking portion may be a substituted or unsubstituted alkylene group having 1 to 30 carbon atoms. In the ligand LG, one or more linking portions may be provided. However, embodiments are not limited thereto, and the linking portion may be omitted from the ligand.

In an embodiment, the ligand LG may be represented by Formula L:

Rₐ-(Lₐ)_{z}-OCH₂CH₂OCH₃ [Formula L]

In Formula L, Rₐ may be a hydroxy group, a thiol group, an amine group, a carboxylic acid group, a dithioacid group, a phosphine group, or a catechol group. For example, Rₐ may be a thiol group, an amine group, or a carboxylic acid group.

In Formula L, Lₐ may be a substituted or unsubstituted alkylene group having 1 to 30 carbon atoms, a substituted or unsubstituted alkenylene group having 2 to 30 carbon atoms, a substituted or unsubstituted arylene group having 6 to 30 ring-forming carbon atoms, or a substituted or unsubstituted heteroarylene group having 2 to 30 ring-forming carbon atoms. For example, Lₐ may be a substituted or unsubstituted methylene group or a substituted or unsubstituted ethylene group.

In Formula L, z may be an integer from 0 to 10. For example, z may be 1.

In Formula L, Rₐ may correspond to the above-described head portion, and *—OCH₂CH₂OCH₃ may correspond to the above-described tail portion. In Formula L, when z is 1 or more, Lₐ may correspond to the above-described linking portion.

In an embodiment, the ligand LG may include at least one of 2-(2-methoxyethoxy)ethanamine, 2-(2-methoxyethoxy) acetic acid, and 2-(2-methoxyethoxy)ethanethiol. The nanoparticles NP according to an embodiment may include ligands LG that are attached to the surface of the core CO and may include a 2-methoxyethoxy group, thereby improving the surface stability of the core CO and exhibiting excellent dispersibility and excellent stability over time in the ink composition ICP.

In an embodiment, an amount of the ligands LG bonded to a surface of the core CO may be in a range of about 10 wt % to about 30 wt % with respect to 100 wt % of a total weight of the nanoparticles NP.

When an amount of the ligands LG in the nanoparticle NP is less than or equal to about 10 wt %, surface stability of the core CO may deteriorate, and thus the light efficiency and service life of the light emitting element ED may be reduced. When an amount of the ligands LG in the nanoparticle NP is less than or equal to about 10 wt %, the dispersibility and stability over time of the nanoparticle NP may be reduced, and thus, solution processability may deteriorate. When an amount of the ligands LG in the nanoparticle NP is greater than or equal to about 30 wt %, the hole transport and hole injection characteristics of the core CO may deteriorate, and thus, charge balance may collapse in the light emitting element ED, thereby deteriorating efficiency and service life. When an amount of the ligands LG in the nanoparticle NP satisfies the above-described range, excellent hole transport and hole injection characteristics may be exhibited, and thus the light efficiency and service life of the light emitting element ED may be improved. When an amount of the ligands LG in the nanoparticle NP satisfies the above-described range, dispersion stability and stability over time may be excellent, and thus the solution processability may be improved.

In the specification, an amount of the ligands LG may represent an amount of the ligands LG present on the surface of the core CO in the nanoparticle NP. An amount of the ligands LG may be measured by Thermogravimetric analysis (TGA), but embodiments are not limited thereto.

In an embodiment, the ink composition ICP may further include an additive AT. The additive AT may be included in the ink composition ICP and may improve the dispersion stability of the nanoparticles NP. When the ink composition ICP includes the additive AT, dispersion stability of the nanoparticles NP may improve, and thus, the solution processability may be further improved.

### In an Embodiment, the Additive AT May be Represented by Formula 2:

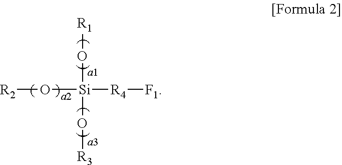

In Formula 2, R₁ to R₃ may each independently be a substituted or unsubstituted alkyl group having 1 to 30 carbon group, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms. In an embodiment, R₁ to R₃ may each independently be a substituted or unsubstituted alkyl group having 1 to 10 carbon atoms. For example, R₁ to R₃ may each independently be a substituted or unsubstituted methyl group or a substituted or unsubstituted ethyl group.

In Formula 2, R₄ may be a substituted or unsubstituted alkylene group having 1 to 30 carbon atoms, a substituted or unsubstituted cycloalkylene group having 3 to 20 ring-forming carbon atoms, a substituted or unsubstituted arylene group having 6 to 30 ring-forming carbon atoms, or a substituted or unsubstituted heteroarylene group having 2 to 30 ring-forming carbon atoms. In an embodiment, R₄ may be a substituted or unsubstituted alkylene group having 1 to 10 carbon atoms.

In Formula 2, a1 to a3 may each independently be 0 or 1. In an embodiment, at least one of a1 to a3 may be 1. For example, any one of a1 to a3 may be 1, and the other two may be 0. For example, two of a1 to a3 may be 1, and the other may be 0. For example, a1 to a3 may each be 1.

In Formula 2, F₁ may be a substituted or unsubstituted (meth)acrylate group, a substituted or unsubstituted epoxy group, or a substituted or unsubstituted amine group. For example, F₁ may be a substituted or unsubstituted (meth)acrylate group.

In an embodiment, the additive represented by Formula 2 may be represented by one of Formula 3-1 to Formula 3-5:

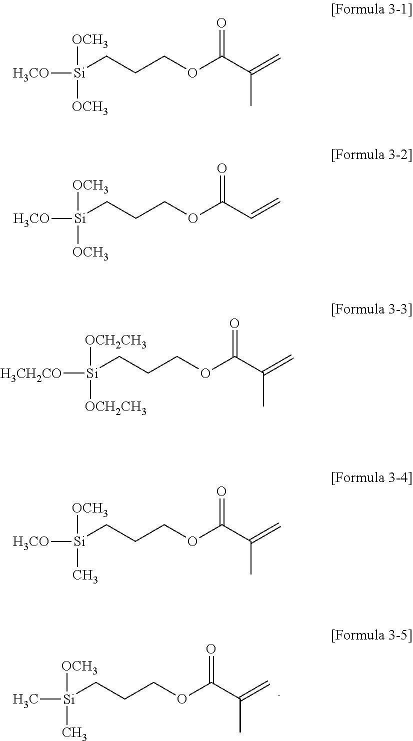

The ink composition ICP according to an embodiment may include a solvent CV. The solvent may be an organic solvent or an inorganic solvent such as water. The organic solvent may include an aprotic solvent or a protic solvent.

For example, the aprotic solvent may include hexane, toluene, chloroform, dimethyl sulfoxide, octane, xylene, hexadecane, cyclohexylbenzene, triethylene glycol monobutyl ether, dimethylformamide, decane, dodecane hexadecene, cyclohexylbenzene, tetrahydronaphthalene, ethyl Ethylnaphthalene, ethylbiphenyl, isopropylnaphthalene, diisopropylnaphthalene, diisopropylbiphenyl, xylene, isopropylbenzene, pentylbenzene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, etc., but embodiments are not limited thereto.

The protic solvent may be a compound capable of providing at least one proton. For example, the protic solvent may be a compound containing at least one dissociable proton. For example, the protic solvent may include a protic liquid material or a protic polymer. The protic solvent may include, for example, methanol, ethanol, propanol, isopropanol, ethylene glycol, propylene glycol, diethylene glycol, or the like, but embodiments are not limited thereto.

In an embodiment, the solvent CV may include a polyethylene glycol moiety. The solvent CV may contain a polyethylene glycol moiety and a first substituent linked to an end of the polyethylene glycol moiety. In an embodiment, the first substituent may be an alkyl group, a cycloalkyl group, a heterocycloalkyl group, a silyl group, an aryl group, or a heteroaryl group. Since the ink composition ICP includes the solvent containing the polyethylene glycol moiety and the first substituent, dispersion stability of the nanoparticles NP may be improved, and thus, the solution processability may be improved. In the specification, the first substituent may be a substituent corresponding to R₁₃ of Formula 3, which will be described below. In an embodiment, the solvent CV may be represented by Formula 3:

R₁₁—O—(R₁₂—O)ₙ—R₁₃ [Formula 3]

In Formula 3, R₁₁ may be a hydrogen atom or a deuterium atom. For example, R₁₁ may be a hydrogen atom.

In Formula 3, R₁₂ may be a substituted or unsubstituted alkylene group having 1 to 60 carbon atoms, a substituted or unsubstituted cycloalkylene group having 3 to 10 ring-forming carbon atoms, a substituted or unsubstituted heterocycloalkylene group having 2 to 10 ring-forming carbon atoms, a substituted or unsubstituted arylene group having 6 to 30 ring-forming carbon atoms, or a substituted or unsubstituted heteroarylene group having 2 to 30 ring-forming carbon atoms. For example, R₁₂ may be a substituted or unsubstituted alkylene group having 1 to 20 carbon atoms. For example, R₁₂ may be a substituted or unsubstituted ethylene group or a substituted or unsubstituted isopropylene group.

In Formula 3, R₁₃ may be a substituted or unsubstituted alkyl group having 1 to 20 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms. In an embodiment, R₁₃ may be a substituted or unsubstituted alkyl group having 1 to 10 carbon atoms, a substituted or unsubstituted heterocycloalkyl group having 2 to 10 ring-forming carbon atoms, or a substituted or unsubstituted aryl group having 6 to 30 ring-forming carbon atoms. For example, R₁₃ may be a substituted or unsubstituted methyl group, a substituted or unsubstituted ethyl group, a substituted or unsubstituted n-propyl group, a substituted or unsubstituted isopropyl group, a substituted or unsubstituted t-butyl group, a substituted or unsubstituted isopentyl group, a substituted or unsubstituted benzyl group, or a substituted or unsubstituted tetrahydrofuranyl group.

In Formula 3, n may be an integer from 1 to 5. For example, n may be an integer from 1 to 3.

In an embodiment, the solvent may be represented by one of Formula 4-1 to Formula 4-3:

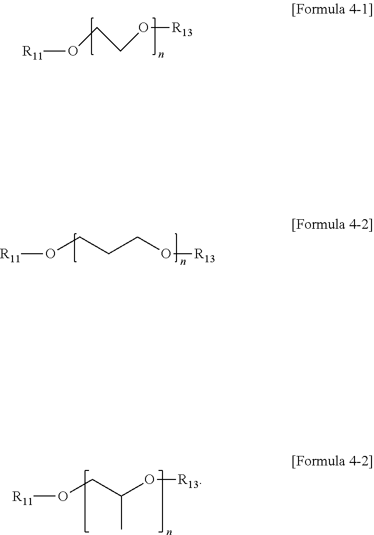

In Formula 4-1 to Formula 4-3, R₁₁, R₁₃, and n may be the same as described in Formula 3.

In an embodiment, the solvent may be represented by one of Formula 5-1 to Formula 5-8:

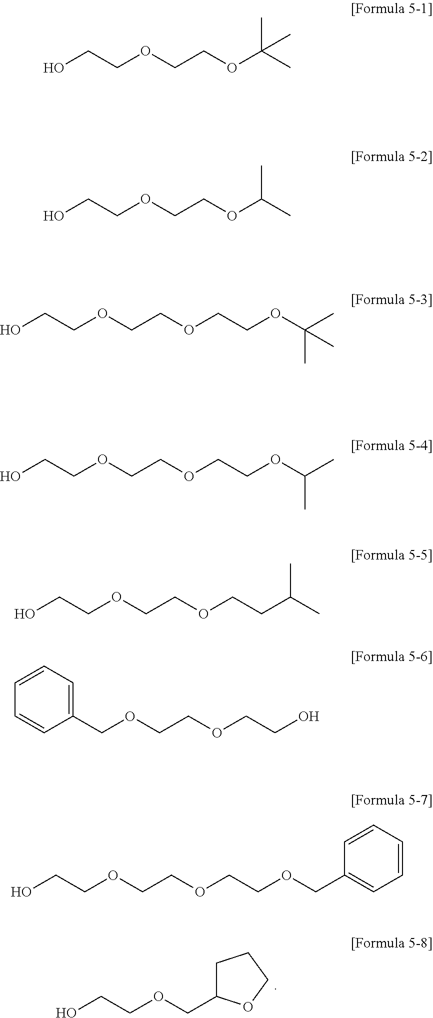

The ink composition ICP according to an embodiment may include the solvent CV represented by Formula 3, and thus the dispersion stability of the nanoparticles NP in the ink composition ICP may be improved. In an embodiment, as the solvent CV represented by Formula 3 is introduced into the ink composition ICP including the nanoparticles NP, the dispersion stability of the nanoparticles NP may be improved, thereby improving the solution processability.

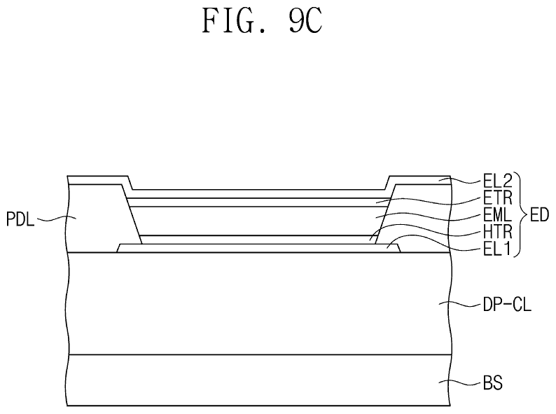

FIGS. 9A to 9C are each a schematic cross-sectional view of method steps for manufacturing a light emitting element according to an embodiment.

FIG. 9A is a schematic cross-sectional view of a step of providing a preliminary hole transport region (S102) among the steps in the method of manufacturing a light emitting element according to an embodiment. The step of providing a preliminary hole transport region (S102) may be a step of applying the ink composition ICP on the first electrode EL1.

In an embodiment, the method of applying the ink composition ICP is not particularly limited, and a spin coating method, a cast method, a LB method (Langmuir-Blodgett), an inkjet printing method, a laser printing method, a laser thermal transfer method (LITI), etc. may be used. For example, the ink composition ICP may be applied on the first electrode EL1 by using an inkjet printing method. FIG. 9A illustrates that the ink composition ICP may be applied onto a space between a pixel defining film PDL through a nozzle NZ, but embodiments are not limited thereto.

FIG. 9B is a schematic cross-sectional view of a step of heat-treating the preliminary hole transport region (S103) in the method of manufacturing a light emitting element according to an embodiment. The step of heat-treating the preliminary hole transport region (S103) may be a step of providing heat LT to the preliminary hole transport region P-HTR and heat-treating the preliminary hole transport region P-HTR at a first temperature for a selected time.

The solvent CV (see FIG. 8) may be removed through the heat-treating step (S103), and accordingly, a uniform thin film may be formed. In an embodiment, the first temperature is not particularly limited, but may be in a range of about 50° C. to about 350° C. For example, the first temperature may be in a range of about 200° C. to about 300° C. However, embodiments are not limited thereto, and the temperature and time of the heat-treating step at the first temperature may be appropriately selected according to the type and capacity of the material.

Referring to FIG. 9C, after the step of forming the hole transport region HTR, a step of forming the emission layer EML, a step of forming the electron transport region ETR, and a step of forming the second electrode EL2 may be sequentially performed.

In an embodiment, the step of forming the emission layer EML may include a step of providing a quantum dot composition containing quantum dots QD-C (see FIGS. 5A and 5B) on the hole transport region HTR to form a preliminary emission layer, and a step of heat-treating the preliminary emission layer. The quantum dot composition may include the quantum dots QD-C (see FIGS. 5A and 5B) and the solvent. The quantum dots QD-C may be the same as what is described with respect to the first to third quantum dots QD-C1, QD-C2, and QD-C3 as described above in FIG. 4.

The solvent included in the quantum dot composition may be removed through a step of heat-treating the preliminary emission layer, and accordingly, a uniform thin film may be formed. The step of heat-treating the preliminary emission layer may be performed under a second temperature condition. The second temperature is not particularly limited, but may be, for example, in a range of about 50° C. to about 350° C. For example, the second temperature may be in a range of about 200° C. to about 300° C. However, embodiments are not limited thereto, and the temperature and time of the heat-treating step at the second temperature may be appropriately selected according to the type and capacity of the material.

After the step of forming the emission layer EML, a step of forming the electron transport region ETR on the emission layer EML may be performed. The step of forming the electron transport region ETR may be performed by using various methods such as a spin coating method, a cast method, a Langmuir-Blodgett (LB) method, an inkjet printing method, a laser printing method, and a laser induced thermal imaging (LITI) method.

In an embodiment, the step of forming the electron transport region ETR may be performed by an inkjet printing method or a spin coating method. In an embodiment, the step of forming the electron transport region ETR may include a step of providing an electron transport composition on the emission layer EML to form a preliminary electron transport region, and a step of heat-treating the preliminary electron transport region. The electron transport composition may contain inorganic particles MP (see FIG. 5B) and a solvent. The inorganic particles MP included in the electron transport composition may be the same as what is described above with respect to FIG. 5B.

The solvent included in the electron transport composition may be removed through the step of heat-treating the preliminary electron transport region, and accordingly, a uniform thin film may be formed. The step of heat-treating the preliminary electron transport region may be performed under a third temperature condition. The third temperature is not particularly limited, but may be in a range of about 50° C. to about 350° C. For example, the third temperature may be in a range of about 200° C. to about 300° C. However, embodiments are not limited thereto, and the temperature and time of the heat-treating step at the second temperature may be appropriately selected according to the type and capacity of the material.

In the method of manufacturing a light emitting element according to an embodiment, when the electron transport region ETR is formed from the electron transport composition, the light emitting element ED having the structure illustrated in FIG. 5B may be formed.

However, embodiments are not limited thereto, and the step of forming the electron transport region ETR may be a step of depositing an electron transport material on the emission layer EML. The light emitting element ED illustrated in FIG. 5A may be formed through a step of forming the electron transport region ETR. The electron transport material for forming the electron transport region ETR may be a material for the electron transport region ETR described above with reference to FIG. 5A.

Although FIGS. 9A to 9C illustrate that the hole transport region HTR and the electron transport region ETR are each provided between the pixel defining film PDL, embodiments are not limited thereto, and the hole transport region HTR and the electron transport region ETR may each be provided in the form of a common layer that overlaps the pixel defining film PDL.

Hereinafter, with reference to the Examples and the Comparative Examples, a nanoparticle according to an embodiment, an ink composition according to an embodiment, and a light emitting element according to an embodiment will be described. The Examples described below are only illustrations to assist the understanding of the embodiments, and the scope thereof is not limited thereto.

### EXAMPLES AND COMPARATIVE EXAMPLES

### 1. Synthesis of Core

### Synthetic Example 1: Ni_{0.99}Zn_{0.01}O Core

Nickel (II) acetate tetrahydrate (9.9 mmol), zinc acetate dihydrate (0.1 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and Ni_{0.99}Zn_{0.01}O inorganic particles synthesized were precipitated using acetone and n-hexane and dispersed in ink.

### Synthetic Example 2: Ni_{0.98}Zn_{0.02}O Core

Nickel (II) acetate tetrahydrate (9.8 mmol), zinc acetate dihydrate (0.2 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and Ni_{0.98}Zn_{0.02}O inorganic particles synthesized were precipitated using acetone and n-hexane and dispersed in ink.

### Synthetic Example 3: Ni_{0.97}Zn_{0.03}O Core

Nickel (II) acetate tetrahydrate (9.7 mmol), zinc acetate dihydrate (0.3 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and Ni_{0.97}Zn_{0.03}O inorganic particles synthesized were precipitated using acetone and n-hexane and dispersed in ink.

### Synthetic Example 4: Ni_{0.98}Mg_{0.02}O Core

Nickel (II) acetate tetrahydrate (9.8 mmol), magnesium acetate tetrahydrate (0.2 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and Ni_{0.98}Zn_{0.02}O inorganic particles synthesized were precipitated using acetone and n-hexane and dispersed in ink.

### Synthetic Example 5: Ni_{0.98}Sn_{0.02}O Core

Nickel (II) acetate tetrahydrate (9.8 mmol), tin (II) chloride (0.2 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and Ni_{0.98}Zn_{0.02}O inorganic particles synthesized were precipitated using acetone and n-hexane and dispersed in ink.

### Synthetic Example 6: NiOₓ Core

Nickel (II) acetate tetrahydrate (10 mmol), and dimethyl sulfoxide (80 mL) were injected into a reactor and stirred for about 240 minutes. The temperature of the reactor is adjusted to 30° C., and a mixed solution of 1 M tetramethylammonium hydroxide pentahydrate (TMAH) and ethanol (10 mL) were injected thereto for 10 minutes. After the TMAH solution injection is completed, the reaction is maintained for 2 hours, and NiOₓ inorganic particles synthesized were precipitated using acetone and n-hexane and dispersed in ink.

### 2. Preparation of Ink Composition

As shown in Table 1, ink compositions containing nanoparticles of Examples and Comparative Examples were prepared. In Examples 1-1 to 1-5 and Comparative Example 1-2, nanoparticles having ligands bonded to the core surface were used, and in Comparative Example 1-1, nanoparticles having no ligands attached to the core surface were used.

TABLE 1

| Division | Core | Ligand |
|---|---|---|
| Ink Composition 1 | Ni_{0.99}Zn_{0.01}O | 2-(2-Methoxyethoxy)ethanethiol |
| Ink Composition 2 | Ni_{0.98}Zn_{0.02}O | 2-(2-Methoxyethoxy)ethanethiol |
| Ink Composition 3 | Ni_{0.97}Zn_{0.03}O | 2-(2-Methoxyethoxy)ethanethiol |
| Ink Composition 4 | Ni_{0.98}Mg_{0.02}O | 2-(2-Methoxyethoxy)ethanethiol |
| Ink Composition 5 | Ni_{0.98}Sn_{0.02}O | 2-(2-Methoxyethoxy)ethanethiol |
| Comparative ink | NiOₓ | — |
| composition 1 | | |
| Comparative ink | NiOₓ | 2-(2-Methoxyethoxy)ethanethiol |
| composition 2 | | |

### 3. Evaluation of Ink Composition

Table 2 shows the evaluation of the ejection properties and average particle size of the ink compositions of Examples and Comparative Examples. In Table 2, the ejection property is evaluated immediately after ejection (day 0) and 7 days after ejection (day 7) of each ink composition from an inkjet facility. The ejection properties were based on a dropping accuracy of ±20 μm, and a Dimatix Materials Printer DMP-2850 was used as the inkjet facility. The average particle size was measured immediately after allowing the ink composition to stand at room temperature (day 0) and 21 days after allowing the ink composition to stand at room temperature (day 21), and the results thereof are shown in Table 2. In Table 2, the particle size was measured using DLS equipment (Nano-ZS90 manufactured by Malvern). The smaller the difference between the initial average particle size and the average particle size after 21 days, the better the dispersion stability for the solvent.

TABLE 2
Ejection property Ejection property

| | | Ejection | Ejection | Average particle | |
|---|---|---|---|---|---|
| | | property | property | size (nm) | |
| Division | Division | (0 day) | (7 day) | 0 days | 21 days |
| Example 1-1 | Ink | ◯ | ◯ | 6.8 | 6.9 |
| | Composition 1 | | | | |
| Example 1-2 | Ink | ◯ | ◯ | 7.1 | 6.9 |
| | Composition 2 | | | | |
| Example 1-3 | Ink | ◯ | ◯ | 6.9 | 7.1 |
| | Composition 3 | | | | |
| Example 1-4 | Ink | ◯ | ◯ | 6.8 | 7.0 |
| | Composition 4 | | | | |
| Example 1-5 | Ink | ◯ | ◯ | 6.7 | 6.6 |
| | Composition 5 | | | | |
| Comparative | Comparative ink | ◯ | X | 7.5 | 140.1 |
| Example 1-1 | composition 1 | | | | |
| Comparative | Comparative ink | ◯ | ◯ | 6.5 | 7.2 |
| Example 1-2 | composition 2 | | | | |

Referring to Table 2, it may be confirmed that Examples 1-1 to 1-5 and Comparative Example 1-2 have good ejection properties even after allowing the ink compositions to stand for 7 days compared to Comparative Example 1-1. Therefore, it may be confirmed that Examples 1-1 to 1-5 and Comparative Example 1-2 have improvement in preservation stability and ejection properties by including the nanoparticles including the ligands bonded to the core surface.

It may be confirmed that Examples 1-1 to 1-5 and Comparative Example 1-2 have a small difference between the initial average particle size and the average particle size after 21 days compared to Comparative Example 1-1. It may be confirmed that Comparative Example 1-1 has excessively increased average particle size after 21 days. Accordingly, it may be confirmed that the ink compositions including the nanoparticles including the core and the ligands bonded to the core surface of Examples 1-1 to 1-5 and Comparative Example 1-2 have excellent dispersion stability. For example, in the case of the ink compositions of Examples 1-1 to 1-5 and Comparative Example 1-2, it may be expected that the dispersion stability of the nanoparticles is improved, and thus the solution processability may be further improved.

### 4. Manufacture of Light Emitting Element

### Manufacture in Example 2-1

An ITO glass substrate (50×50 mm, 15 Ω/cm²), which is a glass substrate for EL-QD (Samsung-Corning Co., Ltd.), was sequentially cleaned using distilled water and isopropanol, and subjected to UV cleaning and ozone cleaning for 30 minutes. PEDOT:PSS (Clevios™ HIL8) was spin-coated on the cleaned glass substrate to form a 100-nm thick film, and baked for about 10 minutes at about 120° C. to form a hole injection layer. Ink Composition 1 was spin-coated on the hole injection layer to form a 40-nm thick film, and baked for about 30 minutes at about 50-350° C. to form a hole transport layer. Green InP QD dispersed in octane was spin-coated on the hole transport layer to form a 40-nm thick film, and baked for about 10 minutes at about 100° C. to form a green emission layer. ZnMgO inorganic nanoparticles were spin-coated on the green emission layer to form a 36-nm thick film, and baked for about 10 minutes at 200° C. to form an electron transport layer. After the glass substrate was mounted on a substrate holder of a vacuum deposition apparatus, AgMg was deposited on the electron transport layer to form a 20-nm thick anode, thereby manufacturing a quantum dot light emitting element. The equipment used for the deposition was a Suicel plus 200 evaporator from Sunic System.

### Manufacture in Example 2-2

An element was manufactured in the same manner as in Example 2-1, except that Ink Composition 2 was used instead of Ink Composition 1 when the hole transport layer was formed.

### Manufacture in Example 2-3

An element was manufactured in the same manner as in Example 2-1, except that Ink Composition 3 was used instead of Ink Composition 1 when the hole transport layer was formed.

### Manufacture in Example 2-4

An element was manufactured in the same manner as in Example 2-1, except that Ink Composition 4 was used instead of Ink Composition 1 when the hole transport layer was formed.

### Manufacture in Example 2-5

An element was manufactured in the same manner as in Example 2-1, except that Ink Composition 5 was used instead of Ink Composition 1 when the hole transport layer was formed.

### Manufacture in Comparative Example 1-1

An element was manufactured in the same manner as in Example 2-1, except that comparative poly(9-vinylcarbazole) (PVK) was used instead of Ink Composition 1 when the hole transport layer was formed.

### Manufacture in Comparative Example 1-2

An element was manufactured in the same manner as in Example 2-1, except that Comparative Ink Composition 2 was used instead of Ink Composition 1 when the hole transport layer was formed.

### 5. Evaluation of Light Emitting Element

Driving voltages, efficiencies, and service lives of the quantum dot light emitting elements manufactured in Examples 2-1 to 2-3 and Comparative Examples 2-1 and 2-2 were measured, and the results are shown in Table 3. Table 3 shows the driving voltage and efficiency at 1280 cd/m² luminance measured using Keithley SMU 236 and a luminance meter PR650. The service life T90 represents the time (hr) taken for the luminance to become 90% when the initial luminance at 10 mA/cm² is set as 100%.

TABLE 3

| | | @1280 nit | | Element |
|---|---|---|---|---|
| | Hole transport | Efficiency | Driving | service life |
| Division | layer material | (cd/A) | voltage (V) | (T90, hr) |
| Example 2-1 | Ni_{0.99}Zn_{0.01}O | 32.0 | 6.0 | 35 |
| Example 2-2 | Ni_{0.98}Zn_{0.02}O | 38.2 | 5.5 | 38 |
| Example 2-3 | Ni_{0.97}Zn_{0.03}O | 20.1 | 6.5 | 16 |
| Example 2-4 | Ni_{0.97}Mg_{0.02}O | 18.2 | 5.7 | 10 |
| Example 2-5 | Ni_{0.97}Sn_{0.02}O | 19.4 | 5.9 | 8 |
| Comparative | PVK | 11.1 | 7.6 | 1 |
| Example 2-1 | | | | |
| Comparative | NiO | 26.0 | 6.2 | 20 |
| Example 2-2 | | | | |

Referring to Table 3, it may be confirmed that the efficiencies and service lives of the light emitting elements of Examples 2-1 to 2-5 and Comparative Example 2-2 to which nickel oxide was applied were increased compared to the light emitting element of Comparative Example 2-1 to which PVK was applied. Through this, it may be seen that the light emitting elements including the hole injection layer to which the nickel oxide was applied of Examples 2-1 to 2-5 and Comparative Example 2-2 exhibit higher efficiency and longer service life characteristics than the light emitting element including the hole injection layer to which the organic material was applied of Comparative Example 2-1. The efficiency and service life of the quantum dot light emitting element are greatly influenced by the charge balance between the electrons and the holes in the emission layer, and in order to balance the charge, the charge injection and transport characteristics of the charge transport layer should be appropriately controlled, and the stability should also be high. An organic material such as PVK, which is a material that may be used as a hole transport material for a quantum dot light emitting element, is advantageous for injecting holes, but may deteriorate when exposed to air, and may deteriorate significantly above a certain temperature, thereby deteriorating the characteristics of the element. In the case of manufacturing a quantum dot light emitting element, a high-temperature process may be used to dry the solvent of the quantum dot composition applied to the emission layer, but since the organic layer under the emission layer is highly likely to be deteriorated in the high-temperature process, there is a limitation in that the efficiency and service life of the light emitting element are deteriorated. Therefore, the light emitting element including the hole transport layer formed of an organic material of Comparative Example 2-1 may exhibit deteriorated characteristics in terms of luminous efficiency and stability compared to Examples. In comparison, Examples 2-1 to 2-5 may exhibit higher chemical stability than Comparative Example 2-1 by using, as a hole transport layer material, a metal oxide in which a first metal is doped into nickel. Therefore, when the hole transport region is formed using the ink composition of Example, the high stability may be exhibited even in the high-temperature process, and thus, the high efficiency and service life may be expected compared to the light emitting element of Comparative Example 2-1.

When Example 2-1 to Example 2-3 are compared, it may be confirmed that Example 2-3 including the nanoparticles having an atomic ratio of the first metal of 0.03 has the deterioration in the efficiency and service life compared to Example 2-1 and Example 2-2 including the nanoparticles having an atomic ratio of the first metal of less than 0.03.

When Example 2-1 to Example 2-5 and Comparative Example 1-2 are compared together, Comparative Example 1-2 to which NiO is applied exhibits higher efficiency and longer service life than Comparative Example 1-1. NiO has a work function similar to that of PEDOT:PSS and has a wide band gap, and thus the hole injection and transport characteristics are good. Here, the properties of the nanoparticles of NiO may be modified by doping the first metal, and thus the hole transport and injection characteristics may be adjusted. Referring to Example 2-1 to Example 2-3, it may be confirmed that as the doping concentration of Zn is increased to 0.02, the efficiency and service life are improved compared to Comparative Example 1-2 to which undoped NiO is applied, but as the doping concentration of Zn is further increased to 0.03, the efficiency and service life are reduced compared to Comparative Example 1-2. This is believed to be a result of the deterioration of the hole injection and transport properties of the hole transport layer due to the over-doping of Zn, resulting in the collapse of the charge balance of the light emitting element. As a result, the hole injection and transport characteristics of the hole transport region may be precisely controlled by adjusting the ratio of nickel and the first metal in the nanoparticles, and accordingly, the charge balance in the emission layer may be optimized. For example, when the atomic ratio of the first metal in the nanoparticles is adjusted to be less than 0.03, the charge balance in the quantum dot emission layer is optimized, and thus the efficiency and service life of the light emitting element may be improved.

In embodiments, since the nanoparticles (NP) represented by Formula 1 may be included in the ink composition forming the hole transport region, the dispersion stability and stability over time may be improved, and thus a uniform thin film may be formed and the charge balance of the element may be controlled through hole injection control and hole transport control. Accordingly, when the hole transport region is formed using the ink composition according to an embodiment, the luminescence characteristics and the element service life characteristics of the light emitting element may be improved. By adjusting the ratio of nickel and the first metal in the nanoparticles, the hole transport and injection characteristics of the nanoparticles may be controlled to improve the charge injection balance of the light emitting element. Therefore, when the hole transport region is formed by applying the ink composition of an embodiment, the current density in the element may be increased, and ultimately, the luminous efficiency and service life of the display device may be improved.

The light emitting element according to an embodiment may exhibit improved element characteristics with high efficiency and a long service life.

The ink composition according to an embodiment may contribute to high efficiency and long service life of the light emitting element.

An embodiment may provide a method for manufacturing a light emitting element having improved process reliability.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode;
an emission layer disposed between the first electrode and the second electrode; and
a hole transport region disposed between the first electrode and the emission layer, the hole transport region comprising nanoparticles, wherein
the nanoparticles each comprise a core represented by Formula 1:
Ni₁₋ₓMₓO [Formula 1]
wherein in Formula 1,
M is Zn, Sn, Ti, Cu, Mg, or Cr, and
x satisfies 0<x<1.

2. The light emitting element of claim 1, wherein x satisfies 0.01≤x<0.03.

3. The light emitting element of claim 1, wherein M is Zn.

4. The light emitting element of claim 1, wherein the nanoparticles each further comprise ligands bonded to a surface of the core.

5. The light emitting element of claim 4, wherein the ligands comprise at least one of 2-(2-methoxyethoxy)ethanamine, 2-(2-methoxyethoxy) acetic acid, and 2-(2-methoxyethoxy)ethanethiol.

6. The light emitting element of claim 4, wherein an amount of the ligands is in a range of about 10 wt % to about 30 wt % with respect to 100 wt % of a total weight of the nanoparticles.

7. The light emitting element of claim 1, wherein the hole transport region further comprises an additive represented by Formula 2: 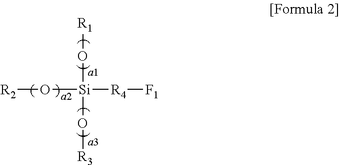
wherein in Formula 2,
R₁ to R₃ are each independently a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms,
R₄ is a substituted or unsubstituted alkylene group having 1 to 30 carbon atoms, a substituted or unsubstituted cycloalkylene group having 3 to 30 ring-forming carbon atoms, a substituted or unsubstituted arylene group having 6 to 60 ring-forming carbon atoms, or a substituted or unsubstituted heteroarylene group having 2 to 60 ring-forming carbon atoms,
a1 to a3 are each independently 0 or 1, provided that at least one of a1 to a3 is 1, and
F₁ is a substituted or unsubstituted (meth)acrylate group, a substituted or unsubstituted epoxy group, or a substituted or unsubstituted amine group.

8. The light emitting element of claim 7, wherein the additive is represented by one of Formula 3-1 to Formula 3-5:

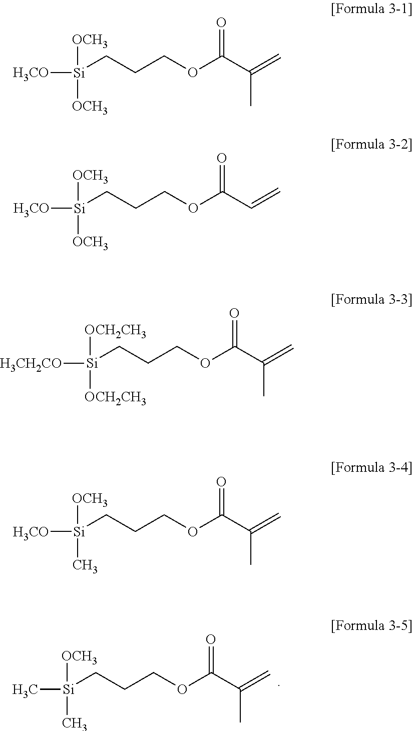

9. The light emitting element of claim 1, wherein the emission layer comprises quantum dots.

10. The light emitting element of claim 1, further comprising:
an electron transport region disposed between the second electrode and the emission layer, wherein
the electron transport region comprises a metal oxide.

11. The light emitting element of claim 10, wherein the metal oxide comprises at least one of ZnO, ZnSnO, ZnMgO, SnO₂, and ZnGaO.

12. An ink composition comprising nanoparticles, wherein the nanoparticles each comprise a core represented by Formula 1:
Ni₁₋ₓMₓO [Formula 1]
wherein in Formula 1,
M is Zn, Sn, Ti, Cu, Mg, or Cr, and
x satisfies 0.01≤x<0.03.

13. The ink composition of claim 12, wherein M is Zn.

14. The ink composition of claim 12, wherein the nanoparticles each further comprise ligands bonded to a surface of the core.

15. The ink composition of claim 14, wherein the ligands comprise at least one of 2-(2-methoxyethoxy)ethanamine, 2-(2-methoxyethoxy) acetic acid, and 2-(2-methoxyethoxy)ethanethiol.

16. The ink composition of claim 14, wherein an amount of the ligands is in a range of about 10 wt % to about 30 wt % with respect to 100 wt % of a total weight of the nanoparticles.

17. The ink composition of claim 12, further comprising an additive represented by Formula 2: 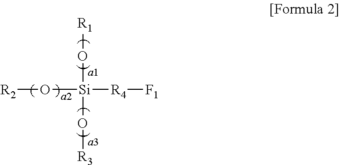
wherein in Formula 2,
R₁ to R₃ are each independently a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms,
R₄ is a substituted or unsubstituted alkylene group having 1 to 30 carbon atoms, a substituted or unsubstituted cycloalkylene group having 3 to 30 ring-forming carbon atoms, a substituted or unsubstituted arylene group having 6 to 60 ring-forming carbon atoms, or a substituted or unsubstituted heteroarylene group having 2 to 60 ring-forming carbon atoms,
a1 to a3 are each independently 0 or 1, provided that at least one of a1 to a3 is 1, and
F₁ is a substituted or unsubstituted (meth)acrylate group, a substituted or unsubstituted epoxy group, or a substituted or unsubstituted amine group.

18. A method for manufacturing a light emitting element, the method comprising:
forming a hole transport region on a first electrode;
forming an emission layer on the hole transport region;
forming an electron transport region on the emission layer; and
forming a second electrode on the electron transport region, wherein the forming of the hole transport region comprises:
preparing an ink composition including nanoparticles;
providing the ink composition on the first electrode to form a preliminary hole transport region; and
heat-treating the preliminary hole transport region, and
the nanoparticles each comprise a core represented by Formula 1:
Ni₁₋ₓMₓO [Formula 1]
wherein in Formula 1,
M is Zn, Sn, Ti, Cu, Mg, or Cr, and
x satisfies 0<x<1.

19. The method of claim 18, wherein the forming of the emission layer comprises:
providing, on the hole transport region, a quantum dot composition including quantum dots to form a preliminary emission layer; and
heat-treating the preliminary emission layer.

20. The method of claim 18, wherein the forming of the electron transport region comprises:
providing, on the emission layer, an electron transport composition including a metal oxide to form a preliminary electron transport region; and
heat-treating the preliminary electron transport region.
